(19) United States
(12) Patent Application Publication
(10) Pub. No.: US 2025/0374785 A1
(43) Pub. Date: Dec. 4, 2025

(54) DISPLAY DEVICE AND ELECTRONIC DEVICE INCLUDING THE SAME

(71) Applicant: Samsung Display Co., Ltd., Yongin-si (KR)

(72) Inventors: Dong Hee SHIN, Yongin-si (KR); Sun Kwun SON, Yongin-si (KR)

(21) Appl. No.: 19/221,294

(22) Filed: May 28, 2025

(30) Foreign Application Priority Data
May 29, 2024 (KR) 10-2024-0069785

(51) Int. Cl. H10K 59/131; H10K 59/88

(52) U.S. Cl. CPC H10K 59/131; H10K 59/88

(57) ABSTRACT

A display device includes: a first sub-pixel and a second sub-pixel arranged along a first direction, and forming a first sub-pixel unit; a third sub-pixel and a fourth sub-pixel arranged along the first direction, and forming a second sub-pixel unit adjacent to the first sub-pixel unit; a pixel circuit in each of the first to the fourth sub-pixels; a vertical bridge line extending in a second direction, and located in each of the first and the second sub-pixel units; a data line extending in the second direction, and spaced from the vertical bridge line; a horizontal bridge line extending in the first direction; and a dummy electrode in a boundary portion between the first sub-pixel unit and the second sub-pixel unit, and electrically connected to the horizontal bridge line. The dummy electrode may be electrically connected to at least one of the first and the second sub-pixel units.

### CROSS-REFERENCE TO RELATED APPLICATION

The present application claims priority to and the benefit of Korean Patent Application Number 10-2024-0069785, filed on May 29, 2024, in the Korean Intellectual Property Office, the entire disclosure of which is incorporated by reference herein.

### BACKGROUND

### 1. Field

Various embodiments of the present disclosure relate to a display device and an electronic device including the display device.

### 2. Description of Related Art

Recently, as interest in information display increases, research and development on display devices have been continuously conducted.

### SUMMARY

Aspects and features of one or more embodiments of the present disclosure are directed to a display device and an electronic device including the display device capable of improving space efficiency.

One or more embodiments of the present disclosure may provide a display device, including: a first sub-pixel and a second sub-pixel arranged along a first direction, and forming a first sub-pixel unit; a third sub-pixel and a fourth sub-pixel arranged along the first direction, and forming a second sub-pixel unit adjacent to the first sub-pixel unit; a pixel circuit in each of the first to the fourth sub-pixels; a vertical bridge line extending in a second direction, and located in each of the first and the second sub-pixel units; a data line extending in the second direction, and spaced from the vertical bridge line; a horizontal bridge line extending in the first direction; and a dummy electrode in a boundary portion between the first sub-pixel unit and the second sub-pixel unit, and electrically connected to the horizontal bridge line. The dummy electrode may be electrically connected to at least one of the first and the second sub-pixel units.

In a plan view, the vertical bridge line may be located closer to an edge of each of the first and the second sub-pixel units than the data line is.

The vertical bridge line may include a first vertical bridge line, a second vertical bridge line, a third vertical bridge line, and a fourth vertical bridge line arranged along the first direction. The first vertical bridge line may overlap the pixel circuit of the first sub-pixel. The second vertical bridge line may overlap the pixel circuit of the second sub-pixel. The third vertical bridge line may overlap the pixel circuit of the third sub-pixel. The fourth vertical bridge line may overlap the pixel circuit of the fourth sub-pixel. In a plan view, the dummy electrode may be between the second vertical bridge line and the third vertical bridge line.

The data line may include a first data line spaced from the first vertical bridge line, a second data line spaced from the second vertical bridge line, a third data line spaced from the third vertical bridge line, and a fourth data line spaced from the fourth vertical bridge line. In a plan view, the second vertical bridge line may be located closer to the dummy electrode than the second data line is, and the third vertical bridge line may be closer to the dummy electrode than the third data line is.

The display device may further include: a first via layer on the horizontal bridge line, and including a first via hole exposing one area of the horizontal bridge line; and a second via layer on the dummy electrode, and including a second via hole exposing one area of the dummy electrode. The first to the fourth vertical bridge lines may be on the second via layer, and the dummy electrode may be between the first via layer and the second via layer. The dummy electrode may be electrically connected to the horizontal bridge line through the first via hole.

A first end of the dummy electrode may be electrically connected to the horizontal bridge line through the first via hole. A second end of the dummy electrode may be electrically connected to at least one of the second vertical bridge line and the third vertical bridge line through the second via hole.

The display device may further include: a first auxiliary conductive pattern under the second vertical bridge line between the first via layer and the second via layer of the second sub-pixel, and electrically connected to the second vertical bridge line; and a second auxiliary conductive pattern under the third vertical bridge line between the first via layer and the second via layer of the third sub-pixel, and electrically connected to the third vertical bridge line. The first and the second auxiliary conductive patterns may be in a same layer as the dummy electrode. The dummy electrode may be integrally formed with at least one of the first or the second auxiliary conductive patterns.

The display device may further include an auxiliary conductive pattern under at least one of the second and the third vertical bridge lines between the first via layer and the second via layer. The auxiliary conductive pattern may be in a same layer as the dummy electrode, and may be integrally formed with the dummy electrode.

In a plan view, the data line may be closer to an edge of each of the first and the second sub-pixel units than the vertical bridge line is.

One or more embodiments of the present disclosure may provide a display device, including: a substrate having a display area including a first area and a second area, and a non-display area around at least one side of the display area; a first sub-pixel and a second sub-pixel arranged along a first direction in each of first and second pixel rows of the substrate, and forming a first sub-pixel unit; a third sub-pixel and a fourth sub-pixel arranged along the first direction in each of the first and second pixel rows of the substrate, and forming a second sub-pixel unit adjacent to the first sub-pixel unit; a pixel circuit in each of the first to the fourth sub-pixels; a vertical bridge line extending in a second direction, and in each of the first and the second sub-pixel units; a data line extending in the second direction, and spaced from the vertical bridge line; a first horizontal bridge line extending in the first pixel row in the first direction; a second horizontal bridge line extending in the second pixel row in the first direction; a first dummy electrode in the first pixel row in a boundary portion between the first sub-pixel unit and the second sub-pixel unit, and electrically connected to the first horizontal bridge line; and a second dummy electrode in the second pixel row in the boundary portion between the first sub-pixel unit and the second sub-pixel unit, and electrically connected to the second horizontal bridge line. In a plan view, the first dummy electrode and the second dummy electrode may be in a same column.

In a plan view, the vertical bridge line may be closer to an edge of each of the first and the second sub-pixel units than the data line is.

The vertical bridge line may include a first vertical bridge line, a second vertical bridge line, a third vertical bridge line, and a fourth vertical bridge line arranged along the first direction in each of the first and the second pixel rows. The first vertical bridge line may overlap the pixel circuit of the first sub-pixel. The second vertical bridge line may overlap the pixel circuit of the second sub-pixel. The third vertical bridge line may overlap the pixel circuit of the third sub-pixel. The fourth vertical bridge line may overlap the pixel circuit of the fourth sub-pixel. In a plan view, each of the first and the second dummy electrodes may be between the second vertical bridge line and the third vertical bridge line.

The data line may include a first data line spaced from the first vertical bridge line, a second data line spaced from the second vertical bridge line, a third data line spaced from the third vertical bridge line, and a fourth data line spaced from the fourth vertical bridge line. In a plan view, the second vertical bridge line may be closer to the first and the second dummy electrodes than the second data line is, and the third vertical bridge line may be closer to the first and the second dummy electrodes than the third data line is.

The first dummy electrode may be electrically connected to at least one of the second or the third vertical bridge lines. The second dummy electrode may be electrically connected to a remaining one of the second and the third vertical bridge lines.

The display device may further include: a first auxiliary conductive pattern overlapping one area of the second vertical bridge line in the second sub-pixel of each of the first and the second pixel rows; and a second auxiliary conductive pattern overlapping one area of the third vertical bridge line in the third sub-pixel of each of the first and the second pixel rows. The first and the second auxiliary conductive patterns in a same layer as the first and the second dummy electrodes. The first dummy electrode may be integrally formed with the second auxiliary conductive pattern. The second dummy electrode may be integrally formed with the first auxiliary conductive pattern.

The display device may further include: a first via layer on the first and the second horizontal bridge lines, and including an 11-th via hole exposing one area of the first horizontal bridge line, and a 12-th via hole exposing one area of the second horizontal bridge line; and a second via layer on the first and the second auxiliary conductive patterns, and including a 21-th via hole exposing one area of the first auxiliary conductive pattern, and a 22-th via hole exposing one area of the second auxiliary conductive pattern. The first to the fourth vertical bridge lines may be on the second via layer. The first and the second dummy electrodes and the first and the second auxiliary conductive patterns may be between the first via layer and the second via layer.

The first dummy electrode may be electrically connected to the first horizontal bridge line through the 11-th via hole, and the second auxiliary conductive pattern integrally formed with the first dummy electrode may be electrically connected to the third vertical bridge line through the 22-th via hole. The second dummy electrode may be electrically connected to the second horizontal bridge line through the 12-th via hole, and the first auxiliary conductive pattern integrally formed with the second dummy electrode may be electrically connected to the second vertical bridge line through the 21-th via hole.

The 11-th via hole and the 12-th via hole may be in the boundary portion between the first sub-pixel unit and the second sub-pixel unit. The 11-th via hole and the 12-th via hole may be in an identical column, in a plan view.

The display device may further include: a second auxiliary conductive pattern under the third vertical bridge line in the first pixel row, and overlapping one area of the third vertical bridge line; and a first auxiliary conductive pattern under the second vertical bridge line in the second pixel row, and overlapping one area of the second vertical bridge line. The first dummy electrode may be integrally formed with the second auxiliary conductive pattern. The second dummy electrode may be integrally formed with the first auxiliary conductive pattern.

In a plan view, the data line may be closer to an edge of each of the first and the second sub-pixel units than is the vertical bridge line.

One or more embodiments of the present disclosure may provide an electronic device, including: a processor configured to provide input image data to a display device; and the display device configured to display an image based on the input image data. The display device comprises a first sub-pixel and a second sub-pixel arranged along a first direction, and forming a first sub-pixel unit; a third sub-pixel and a fourth sub-pixel arranged along the first direction, and forming a second sub-pixel unit adjacent to the first sub-pixel unit; a pixel circuit in each of the first to the fourth sub-pixels; a vertical bridge line extending in a second direction, and located in each of the first and the second sub-pixel units; a data line extending in the second direction, and spaced from the vertical bridge line; a horizontal bridge line extending in the first direction; and a dummy electrode in a boundary portion between the first sub-pixel unit and the second sub-pixel unit, and electrically connected to the horizontal bridge line. The dummy electrode is electrically connected to at least one of the first and the second sub-pixel units.

### BRIEF DESCRIPTION OF THE DRAWINGS

FIG. 1 is a schematic plan view illustrating a display device in accordance with one or more embodiments.

FIG. 2 is a schematic plan view illustrating a display device in accordance with one or more embodiments.

FIG. 3 is an enlarged schematic view illustrating a portion EA1 of FIG. 2.

FIG. 4 is a diagram illustrating an example of a display area of a display panel included in the display device of FIG. 2.

FIG. 5 is a circuit diagram illustrating an example of a sub-pixel included in the display area of FIG. 1.

FIG. 6 is a schematic sectional view illustrating one area of the display device in accordance with one or more embodiments.

FIG. 7 is a schematic plan view illustrating sub-pixels positioned in one area of the display area of the display device in accordance with one or more embodiments.

FIG. 8 is a schematic plan view illustrating only components included in first, second, fifth, sixth, seventh, and eighth transistors and a first conductive layer in FIG. 7.

FIG. 9 is a schematic plan view illustrating only components included in a second conductive layer in FIG. 7.

FIG. 10 is a schematic plan view illustrating only components included in third and fourth transistors and a third conductive layer in FIG. 7.

FIG. 11 is a schematic plan view illustrating only components included in a fourth conductive layer in FIG. 7.

FIG. 12 is a schematic plan view illustrating only components included in a fifth conductive layer in FIG. 7.

FIG. 13 is a schematic plan view illustrating only components included in a sixth conductive layer in FIG. 7.

FIG. 14 is a schematic plan view illustrating only components included in the fourth conductive layer, the fifth conductive layer, and the sixth conductive layer in FIG. 7.

FIG. 15 is an enlarged schematic view showing a portion EA2 of FIG. 14.

FIG. 16 is a schematic sectional view taken along the line I-l′ of FIG. 15.

FIG. 17 is a schematic plan view illustrating sub-pixels arranged in first and second pixel rows positioned in one area of the display area of the display device in accordance with one or more embodiments.

FIG. 18 is a schematic view illustrating positions of a first via hole and a second via hole in one area of the display area of the display device in accordance with one or more embodiments.

FIG. 19 is a schematic plan view illustrating sub-pixels positioned in one area of the display area of the display device in accordance with one or more embodiments.

FIGS. 20 and 21 are enlarged schematic views illustrating a portion EA3 of FIG. 19.

FIG. 22 is a schematic plan view illustrating sub-pixels arranged in first and second pixel rows positioned in one area of the display area of the display device in accordance with one or more embodiments.

FIG. 23 is a schematic view illustrating positions of a first via hole and a second via hole in one area of the display area of the display device in accordance with one or more embodiments.

FIG. 24 is a schematic plan view illustrating sub-pixels arranged in first and second pixel rows positioned in one area of the display area of the display device in accordance with one or more embodiments.

FIG. 25 is an enlarged schematic view showing a portion EA4 of FIG. 24.

FIG. 26 is a schematic sectional view taken along the line II-II′ of FIG. 25.

FIG. 27 is a schematic block diagram illustrating an electronic device in accordance with an embodiment.

FIG. 28 is a schematic diagram illustrating an example where the electronic device of FIG. 27 is implemented as a smartphone.

FIG. 29 is a schematic diagram illustrating an example where the electronic device of FIG. 27 is implemented as a tablet computer.

### DETAILED DESCRIPTION

As the present disclosure allows for various changes and numerous embodiments, particular embodiments will be illustrated in the drawings and described in detail in the written description. However, this is not intended to limit the present disclosure to particular modes of practice, and it is to be appreciated that all changes, equivalents, and substitutes that do not depart from the technical scope of the present disclosure are encompassed in the present disclosure.

Throughout the present disclosure, like reference numerals refer to like parts throughout the various figures and embodiments of the present disclosure. The sizes of elements in the accompanying drawings may be exaggerated for clarity of illustration. It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof. Furthermore, in case that a first part such as a layer, a film, a region, or a plate is disposed on a second part, the first part may be not only directly on the second part but a third part may intervene between them. In addition, in case that it is expressed that a first part such as a layer, a film, a region, or a plate is formed on a second part, the surface of the second part on which the first part is formed is not limited to an upper surface of the second part but may include other surfaces such as a side surface or a lower surface of the second part. To the contrary, in case that a first part such as a layer, a film, a region, or a plate is under a second part, the first part may be not only directly under the second part but a third part may intervene between them.

Embodiments and required details of the present disclosure are described with reference to the accompanying drawings in order to describe the present disclosure in detail so that those having ordinary knowledge in the technical field to which the present disclosure pertains can easily practice the present disclosure. Furthermore, a singular form may include a plural form as long as it is not specifically mentioned in a sentence.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within about ±30%, ±20%, ±10%, ±5% of the stated value.

In the description, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the description, the phrase “at least one of” is intended to include the meaning of “at least one selected from the group of” for the purpose of its meaning and interpretation. For example, “at least one of A and B” may be understood to mean “A, B, or A and B.”

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

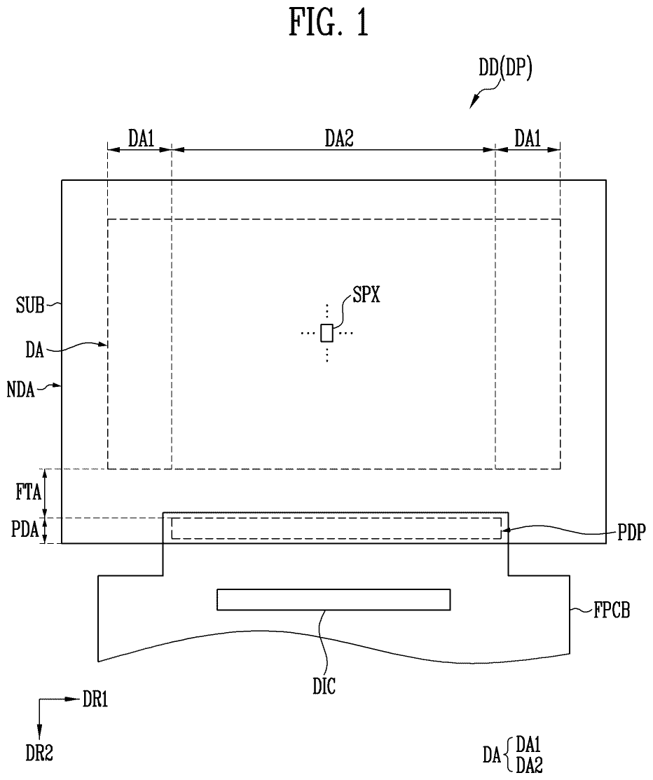

FIG. 1 is a schematic plan view illustrating a display device DD in accordance with one or more embodiments.

In FIG. 1, for the sake of convenience in explanation, there is schematically illustrated the display device DD, for example, the structure of a display panel DP provided in the display device DD, centered on a display area DA in which an image is displayed.

Referring to FIG. 1, the display device DD (or the display panel DP) may include a substrate SUB, and sub-pixels SPX.

The display device DD may be provided in one or more forms, for example, in the form of a rectangular plate having two pairs of parallel sides, but the present disclosure is not limited thereto. If the display device DD is an electronic device having a display surface on at least one surface thereof, e.g., a smartphone, a television, a tablet PC, a mobile phone, a video phone, an electronic reader, a desktop PC, a laptop PC, a netbook computer, a workstation, a server, a PDA, a portable multimedia player (PMP), an MP3 player, a medical appliance, a camera, and/or a wearable device, the present embodiment may be applied to the display device DD.

The substrate SUB may include transparent insulating material to allow light transmission. The substrate SUB may be a rigid substrate or a flexible substrate.

For example, the rigid substrate may be a glass substrate, a quartz substrate, a glass ceramic substrate, and/or a crystalline glass substrate.

The flexible substrate may be either a film substrate or a plastic substrate that includes polymer organic material. For example, the flexible substrate may include polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and/or cellulose acetate propionate.

One area of the substrate SUB may be provided as the display area DA in which the sub-pixels SPX are disposed, and the other area of the substrate SUB may be provided as a non-display area NDA. The non-display area NDA may be disposed around the display area DA along an edge or a periphery of the display area DA.

In one or more embodiments, the display area DA may include a first area DA1 and a second area DA2. For example, the display area DA may include a second area DA2 positioned in a central portion thereof, and first areas DA1 disposed on opposite sides of the second area DA2. The first areas DA1 may be areas positioned in an outer direction of the display panel DP rather than in the central portion thereof with respect to the second area DA2, but is not limited thereto.

The sub-pixels SPX may be disposed in each of the first area DA1 and the second area DA2.

Each of the sub-pixels SPX may include a light emitting element including an emission layer. In one or more embodiments, the light emitting element may include an organic light emitting diode (OLED) or inorganic light emitting diode having a size of a micro- to nano-scale (or -meter) range, but is not limited thereto.

The display device DD may display images in the first area DA1 and the second area DA2 by driving the sub-pixels SPX in response to input image data.

In one or more embodiments, the display area DA may include a sensing area capable of sensing a fingerprint of a user, and/or the like. For example, the first areas DA1 and the second area DA2 may be set to sensing areas capable of sensing the fingerprint of the user, and/or the like. In the case where the entirety of the display area DA is set to the sensing area, the non-display area NDA enclosing the display area DA may be set to a non-sensing area.

The non-display area NDA may include a fan-out area FTA and a pad area PDA.

The pad area PDA may be positioned closest to an edge of the non-display area NDA.

The fan-out area FTA may be disposed in the non-display area NDA at a position adjacent to the display area DA. For example, the fan-out area FTA may be one area of the non-display area NDA that is positioned between the pad area PDA and the display area DA. In one or more embodiments, the non-display area NDA may include an antistatic circuit area in which there is disposed an antistatic circuit which is electrically connected to signal lines disposed in the display area DA and is configured to prevent static electricity from occurring.

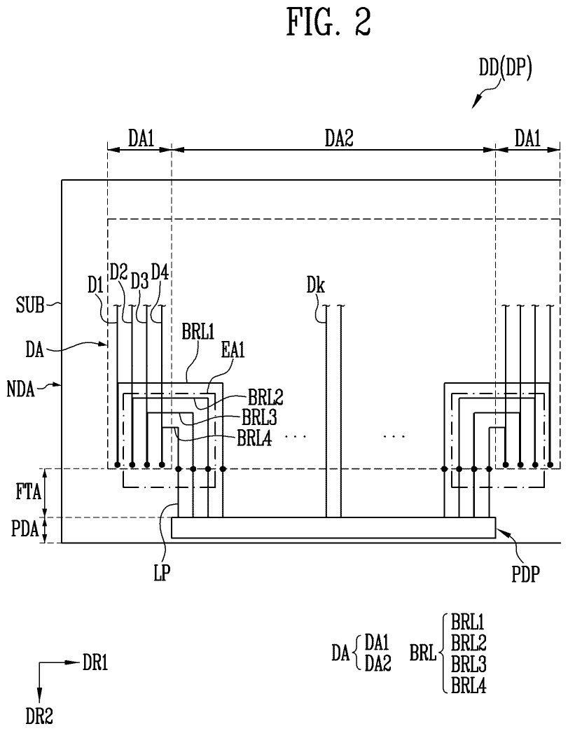

A line component (refer to “LP” of FIG. 2) may be disposed in the fan-out area FTA. A pad component PDP may be disposed in the pad area PDA.

The display device DD may include a circuit substrate or a circuit board FPCB connected to the display panel DP through the pad component PDP. The circuit board FPCB may be a flexible printed circuit board, but the present disclosure is not limited thereto.

The circuit board FPCB may process various signals input from a printed circuit board (PCB) and output the processed signals to the display panel DP. To this end, a first end of the circuit board FPCB may be attached to the display panel DP, and a second end thereof opposite to the first end may be attached to the printed circuit board. The circuit board FPCB may be connected to each of the display panel DP and the printed circuit board by a conductive adhesive component (e.g., an anisotropic conductive film).

A driver DIC may be mounted on the circuit board FPCB. For example, the driver DIC may be an integrated circuit (IC). The driver DIC may include a panel driver, and/or the like.

The panel driver may sequentially scan the sub-pixels SPX and supply data signals corresponding to an image data signal to the sub-pixels SPX. In this case, the display panel DP may display an image corresponding to the image data. In accordance with one or more embodiments, the panel driver may supply driving signals for fingerprint sensing to the sub-pixels SPX.

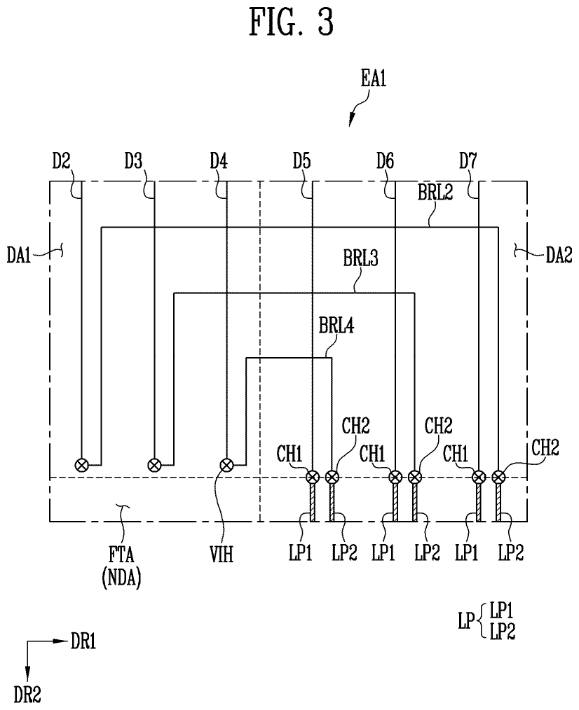

FIG. 2 is a schematic sectional view illustrating a display device DD in accordance with one or more embodiments. FIG. 3 is an enlarged schematic view illustrating a portion EA1 of FIG. 2.

The description with reference to FIGS. 2 and 3 will be focused on differences from the above-mentioned embodiment so as to avoid redundant description.

Referring to FIGS. 2 and 3, the display device DD (or the display panel DP) may include a substrate SUB, a line component LP, and a pad component PDP.

The pad component PDP may be positioned in the pad area PDA of the non-display area NDA, and may be electrically connected to the line component LP.

The line component LP may be positioned in the fan-out area FTA of the non-display area NDA, and may be electrically connected to the sub-pixels (refer to “SPX” of FIG. 1) so that certain signals supplied from the driver (refer to “DIC” of FIG. 1) can be transmitted to the signal lines. The line component LP may include fan-out lines electrically connecting the driver DIC and the sub-pixels SPX in the fan-out area FTA.

In one or more embodiments, the line component LP may be positioned in an intermediate portion of the fan-out area FTA that corresponds to the second areas DA2 of the display area DA. The line component LP may include first lines LP1 and second lines LP2. The first lines LP1 may be electrically connected to data lines D5, D6, D7, . . . . Dk positioned in the second area DA2 of the display area DA through first contact holes CH1. The second lines LP2 may be electrically connected to data lines D1, D2, D3, and D4 positioned in the first area DA1 of the display area DA through second contact holes CH2 and bridge lines BRL (e.g., BRL1, BRL2, BRL3, and BRL4).

The substrate SUB may include a display area DA and a non-display area NDA. The display area DA may be divided into the first area DA1 and the second area DA2.

Signal lines may be disposed in the first area DA1 and the second area DA2 so that various signals can be applied to the signal lines. For example, the data lines D1 to Dk may be disposed in the first area DA1 and the second area DA2 so that data signals can be applied to the data lines D1 to Dk to adjust the brightness of the respective sub-pixels SPX. Various signal lines such as a power line and scan lines, in addition to the data lines D1 to Dk, may be disposed in the first area DA1 and the second area DA2.

In the first area DA1 and the second area DA2, the sub-pixels SPX may be disposed or positioned in areas (e.g., pixel areas) divided by the scan lines and the data lines (e.g., D1 to Dk). The data lines D1 to Dk may extend in a second direction DR2 in the display area DA. In FIGS. 2 and 3, the first to fourth data lines D1 to D4 may be positioned in the first area DA1 (hereinafter, referred to as “1-1-th area”) adjacent to one side (e.g., a left side) of the second area DA2. Furthermore, four data lines may be disposed in the first area DA1 (hereinafter, referred to as “1-2-th area”) adjacent to the other side (e.g., a right side) of the second area DA2. For the sake of convenience in explanation, four data lines are illustrated as being disposed in each of the first areas DA1, but the present disclosure is not limited thereto.

The fifth to k-th data lines D5 to Dk positioned in the second area DA2 may be electrically connected to the respective first lines LP1. For example, in the second area DA2, each of the fifth data line D5, the sixth data line D6, and the seventh data line D7 may be electrically connected to the corresponding first line LP1 through the corresponding first contact hole CH1.

The first to fourth data lines D1 to D4 positioned in the 1-1-th area DA1 may be electrically connected to respective bridge lines BRL. The four data lines positioned in the 1-2-th area DA1 may also be electrically connected to respective bridge lines BRL. The bridge lines BRL may be disposed to bypass a portion of the display area DA adjacent to the non-display area NDA, thus passing through the display area DA.

In the 1-1-th area DA1, the first data line D1 may be electrically connected to a first bride line BRL1, the second data line D2 may be electrically connected to a second bridge line BRL2, the third data line D3 may be electrically connected to a third bridge line BRL3, and the fourth data line D4 may be electrically connected to a fourth bridge line BRL4.

Each of the first to fourth bridge lines BRL1 to BRL4 may extend from the second area DA2 to the 1-1-th area DA1. For example, each of the first to fourth bridge lines BRL1 to BRL4 may be routed from the central portion (or inner portion) of the display area DA to an edge (or outer portion) of the display area DA. The first to fourth bridge lines BRL1 to BRL4 may be electrically connected to the first to fourth data lines D1 to D4 through via holes VIH, respectively, and each may be electrically connected to the corresponding second line LP2 through the corresponding second contact hole CH2.

In FIG. 3, the second bridge line BRL2 may include a first end of electrically connected to the corresponding second line LP2 through the associated second contact hole CH2, and a second end electrically connected to the second data line D2 through the corresponding via hole VIH. The third bridge line BRL3 may include a first end electrically connected to the corresponding second line LP2 through the associated second contact hole CH2, and a second end electrically connected to the third data line D3 through the corresponding via hole VIH. The fourth bridge line BRL4 may include a first end electrically connected to the corresponding second line LP2 through the associated second contact hole CH2, and a second end electrically connected to the fourth data line D4 through the corresponding via hole VIH.

The first end of each of the second to fourth bridge lines BRL2 to BRL4 may be electrically connected to the corresponding second line LP2 through the associated second contact hole CH2 between the second display area DA2 and the non-display area NDA, and the second end thereof may be electrically connected to a corresponding one of the second to fourth data lines D2 to D4 through the associated via hole VIH in the 1-1-th area DA1. In other words, each of the second to fourth bridge lines BRL2 to BRL4 may receive an input signal (e.g., a data signal) from the corresponding second line LP2, and transmit the input signal to a corresponding one of the second to fourth data lines D2 to D4. The second to fourth bridge lines BRL2 to BRL4 may be disposed in a layer that is the same as (e.g., identical to) or different from that of the second line LP2.

The fifth to seventh data lines D5 to D7 in FIG. 3 may be disposed in the same layer, or some thereof may be disposed in different layers. For example, the fifth to seventh data line D5 to D7 may be alternately disposed in different layers.

As described above, in some areas (e.g., the first area DA1) of the display area DA, the data lines may not be directly connected to the line component LP, and may be configured such that input signals of the line component LP are transmitted to the data lines through the bridge lines BRL bypassing a portion of the display area DA, whereby the surface area of the non-display area NDA outside the display area DA can be effectively reduced.

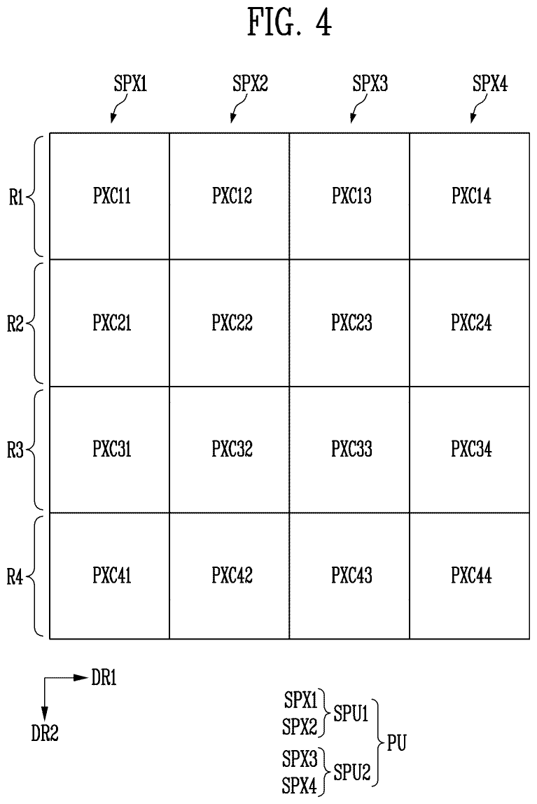

FIG. 4 is a diagram illustrating an example of the display area DA of the display panel DP included in the display device DD of FIG. 2.

Referring to FIGS. 2 and 4, sub-pixels may be disposed in the display area DA of the display panel DP.

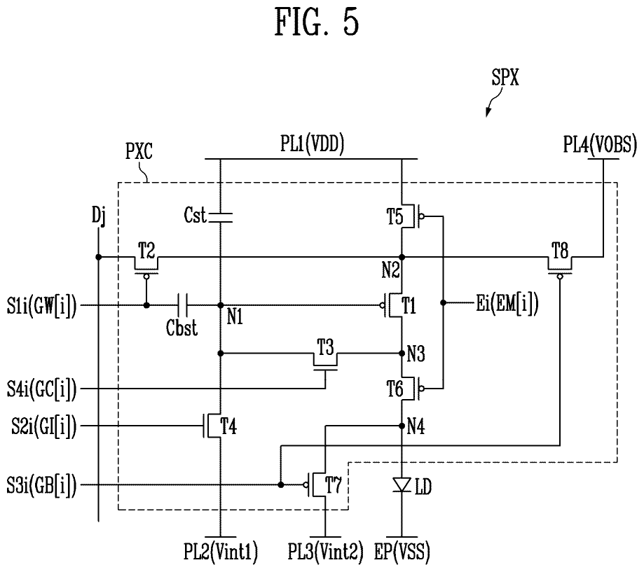

The display area DA may be divided into pixel rows R1 to R4. The pixel rows R1 to R4 may extend in a first direction DR1, and may be arranged along the second direction DR2. Each of the pixel rows R1 to R4 may include sub-pixels SPX1 to SPX4. Each of the sub-pixels SPX1 to SPX4 may include one of pixel circuits PXC11 to PXC44 and a light emitting element (refer to “LD” in FIG. 5).

In one or more embodiments, in each of the first to fourth pixel rows R1 to R4, the sub-pixels SPX1 to SPX4 may be arranged in the order of the first sub-pixel SPX1, the second sub-pixel SPX2, the third sub-pixel SPX3, and the fourth sub-pixel SPX4 along the first direction DR1.

The first sub-pixel SPX1 and the second sub-pixel SPX2 may form a first sub-pixel unit SPU1. The third sub-pixel SPX3 and the fourth sub-pixel SPX4 may form a second sub-pixel unit SPU2. The first and second sub-pixel units SPU1 and SPU2 that are adjacent to each other may be understood as constituting one pixel unit PU.

In the first pixel row R1 (or a first horizontal line), the pixel circuits PXC11 to PXC14 that respectively correspond to the sub-pixels SPX1 to SPX4 of the first pixel row R1 may be arranged along the first direction DR1. In the second pixel row R2 (or a second horizontal line), the pixel circuits PXC21 to PXC24 that respectively correspond to the sub-pixels SPX1 to SPX4 of the second pixel row R2 may be arranged along the first direction DR1. In the third pixel row R3 (or a third horizontal line), the pixel circuits PXC31 to PXC34 that respectively correspond to the sub-pixels SPX1 to SPX4 of the third pixel row R3 may be arranged along the first direction DR1. In the fourth pixel row R4 (or a fourth horizontal line), the pixel circuits PXC41 to PXC44 that respectively correspond to the sub-pixels SPX1 to SPX4 of the fourth pixel row R4 may be arranged along the first direction DR1.

The first, second, third, and fourth sub-pixels SPX1, SPX2, SPX3, and SPX4 of each of the first to fourth pixel rows R1 to R4 may be included in one pixel unit PU.

FIG. 5 is a circuit diagram illustrating an example of the sub-pixel SPX included in the display area DA of FIG. 1. For convenience of description, FIG. 5 illustrates the sub-pixel SPX that is positioned on an i-th horizontal line (or an i-th pixel row) and connected to a j-th data line Dj.

Referring to FIGS. 1 and 5, the sub-pixel SPX may be disposed on the i-th horizontal line.

The sub-pixel SPX may include a light emitting element LD and a pixel circuit PXC. In one or more embodiments, the pixel circuit PXC may include first, second, third, fourth, fifth, sixth, seventh, and eighth transistors T1, T2, T3, T4, T5, T6, T7, and T8 a storage capacitor Cst, and a boost capacitor Cbst.

The first transistor T1 (or a driving transistor) may be electrically connected between a first power line PL1 and a first electrode (or an anode electrode) of the light emitting element LD. The first transistor T1 may include a gate electrode electrically connected to a first node N1. The first transistor T1 may control, based on the voltage of the first node N1, the amount of current (or driving current) flowing from the first power line PL1 to an electrode EP (or a power line) via the light emitting element LD. A first power voltage VDD may be supplied to the first power line PL1. A second power voltage VSS may be supplied to the electrode EP. The first power voltage VDD may be set to a voltage higher than the second power voltage VSS.

The second transistor T2 may be electrically connected between the j-th data line Dj and a second node N2. A gate electrode of the second transistor T2 may be connected to a 1i-th scan line S1i (or a first scan line). When a first scan signal GW[i] (e.g., a first scan signal of a low level) is supplied to the 1i-th scan line S1i, the second transistor T2 may be turned on to electrically connect the j-th data line Dj to the second node N2. In the case where each of the first transistor T1 and the third transistor T3 is turned on, the second transistor T2 may transmit a data signal of the j-th data line Dj to the second node N2 in response to the first scan signal GW[i].

The third transistor T3 may be electrically connected between the first node N1 and a third node N3. A gate electrode of the third transistor T3 may be electrically connected to a 4i-th scan line S4i (or a fourth scan line). The third transistor T3 may be turned on when a fourth scan signal GC]i] is supplied to the 4i-th scan line S4i. If the third transistor T3 is turned on, the first transistor T1 may have a diode-connected form as the first transistor T1 is connected between the second node N2 and the third node N3 and the gate electrode of the first transistor is connected to the first node N1.

The fourth transistor T4 may be electrically connected between the first node N1 and a second power line PL2. A gate electrode of the fourth transistor T4 may be electrically connected to a 2i-th scan line S2i (or a second scan line). A first initialization power voltage Vint1 may be provided to the second power line PL2. The fourth transistor T4 may be turned on by a second scan signal GI[i] supplied to the 2i-th scan line S2i. If the fourth transistor T4 is turned on, the first initialization power voltage Vint1 may be supplied to the first node N1 (i.e., the gate electrode of the first transistor T1).

The fifth transistor T5 may be electrically connected between the first power line PL1 and the second node N2. A gate electrode of the fifth transistor T5 may be electrically connected to an i-th emission control line Ei. The sixth transistor T6 may be electrically connected between the third node N3 and the light emitting element LD (or a fourth node N4). A gate electrode of the sixth transistor T6 may be electrically connected to the i-th emission control line Ei. The fifth transistor T5 and the sixth transistor T6 may be turned off when an emission control signal EM[i] (e.g., an emission control signal EM[i] of a high level) is supplied to the i-th emission control line Ei, and may be turned on when an emission control signal EM[i] of a low level is supplied to the i-th emission control line Ei.

The seventh transistor T7 may be electrically connected between the first electrode (i.e., the fourth node N4) of the light emitting element LD and a third power line PL3. A gate electrode of the seventh transistor T7 may be electrically connected to a 3i-th scan line S3i. A second initialization power voltage Vint2 may be provided to the third power line PL3. In one or more embodiments, the second initialization power voltage Vint2 may be the same as (e.g., identical to) or different from the first initialization power voltage Vint1. The seventh transistor T7 may be turned on by a third scan signal GB[i] supplied to the 3i-th scan line S3i to supply the second initialization power voltage Vint2 to the first electrode of the light emitting element LD (i.e., the fourth node N4).

The eighth transistor T8 may be electrically connected between the second node N2 and a fourth power line PL4. A gate electrode of the eighth transistor T8 may be electrically connected to the 3i-th scan line S3i. A bias voltage VOBS may be supplied to the fourth power line PL4. The eighth transistor T8 may be turned on by the third scan signal GB[i] supplied to the 3i-th scan line S3i to supply the bias voltage VOBS to the second node N2.

The storage capacitor Cst may be connected or formed between the first power line PL1 and the first node N1.

The boost capacitor Cost (or a capacitor) may be connected or formed between the gate electrode of the second transistor T2 and the gate electrode of the first transistor T1 (i.e., the first node N1).

The light emitting element LD may include a first electrode (or an anode electrode) and a second electrode (or a cathode electrode). The first electrode may be connected to the fourth node N4, and the second electrode may be connected to the electrode EP. The second electrode of the light emitting element LD may be supplied with the second power voltage VSS. The light emitting element LD may receive driving current from the first transistor T1 and emit light.

In one or more embodiments, the pixel circuit PXC may include a P-type transistor and an N-type transistor. Each of the third transistor T3 and the fourth transistor T4 may be formed of an oxide semiconductor transistor including an oxide semiconductor (or a second type semiconductor). For example, each of the third transistor T3 and the fourth transistor T4 may be formed of an N-type oxide semiconductor transistor, and include an oxide semiconductor layer as an active layer, but is not limited thereto.

The other transistors (e.g., the first, second, fifth, sixth, seventh, and eighth transistors T1, T2, T5, T6, T7, and T8) may be formed of a poly-silicon transistor including a silicon semiconductor (or a first type semiconductor), and may include a poly-silicon semiconductor layer as an active layer. For example, the active layer may be formed through a low-temperature polysilicon (LTPS) process.

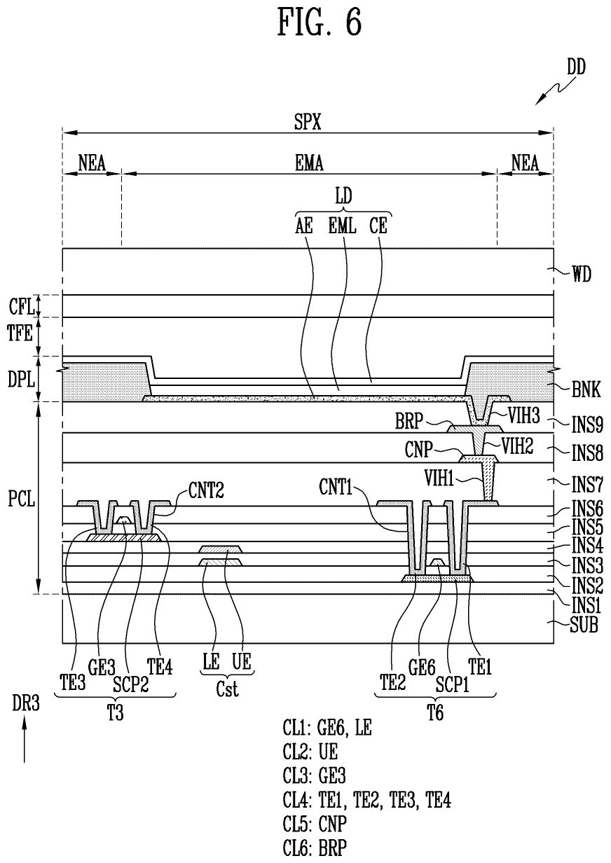

Hereinafter, descriptions will be provided with reference to FIG. 6, focusing a stacked structure (or a cross-sectional structure) of the sub-pixel SPX including the light emitting element LD.

FIG. 6 is a schematic sectional view illustrating one area of the display device DD in accordance with one or more embodiments.

FIG. 6 illustrates a cross-section of a portion corresponding to the third transistor T3 and a cross-section of a portion corresponding to the sixth transistor T6 from among the first to eighth transistors T1 to T8 shown in FIG. 5.

Referring to FIG. 6, the display device DD may include a sub-pixel SPX provided in one area of the substrate SUB.

A pixel circuit layer PCL of the sub-pixel SPX may be disposed on the substrate SUB. At least one or more insulating layers may be disposed in the pixel circuit layer PCL. The insulating layer may include a first insulating layer INS1, a second insulating layer INS2, a third insulating layer INS3, a fourth insulating layer INS4, a fifth insulating layer INS5, a sixth insulating layer INS6, a seventh insulating layer INS7, an eighth insulating layer INS8, and a ninth insulating layer INS9 that are sequentially stacked on the substrate SUB in a third direction DR3.

The first insulating layer INS1 (or a buffer layer) may be disposed on the substrate SUB. The first insulating layer INS1 may prevent impurities from diffusing into the third transistor T3 and the sixth transistor T6. The first insulating layer INS1 may be formed of an inorganic layer including an inorganic material (or substance). The first insulating layer INS1 may include silicon nitride (SiNₓ), silicon oxide (SiOₓ), silicon oxynitride (SiOₓN_{y}), and/or aluminum oxide (AlOₓ). Although the first insulating layer INS1 may have a single-layer structure, the first insulating layer INS1 may have a multilayer structure having at least two or more layers. The first insulating layer INS1 may be omitted depending on the material of the substrate SUB or processing conditions.

The second insulating layer INS2 (or a first gate insulating layer) may be disposed on the first insulating layer INS1. The second insulating layer INS2 may include the same material as the first insulating layer INS1, or may include suitable (or selected) materials from among example materials listed as the constituent material of the first insulating layer INS1. For example, the second insulating layer INS2 may be formed of an inorganic layer including an inorganic material.

The third insulating layer INS3 (or a second gate insulating layer) may be disposed on the second insulating layer INS2. The third insulating layer INS3 may include the same material as the first insulating layer INS1, or may include one or more suitable (or selected) materials from among example materials listed as the constituent material of the first insulating layer INS1.

The fourth insulating layer INS4 (or a first interlayer insulating layer) may be disposed on the third insulating layer INS3. The fourth insulating layer INS4 may be an inorganic layer including inorganic material or an organic layer including an organic material.

The fifth insulating layer INS5 (or a third gate insulating layer) may be disposed on the fourth insulating layer INS4. The fifth insulating layer INS5 may be an inorganic layer including inorganic material or an organic layer including an organic material.

The sixth insulating layer INS6 (or a second interlayer insulating layer) may be disposed on the fifth insulating layer INS5. The sixth insulating layer INS6 may be an inorganic layer including inorganic material or an organic layer including an organic material.

The seventh insulating layer INS7 (or a first via layer) may be disposed on the sixth insulating layer INS6. The seventh insulating layer INS7 may be an inorganic layer including an inorganic material or an organic layer including an organic material. The inorganic layer may include, for example, silicon oxide (SiOₓ), silicon nitride (SiNₓ), silicon oxynitride (SiOₓN_{y}), and/or aluminum oxide (AlOₓ). The organic layer may include, for example, at least one of polyacrylates resin, epoxy resin, phenolic resin, polyamides resin, polyimides rein, unsaturated polyesters resin, poly-phenylen ethers resin, poly-phenylene sulfides resin, and/or benzocyclobutene resin. In one or more embodiments, the seventh insulating layer INS7 may be an organic layer.

The eighth insulating layer INS8 (or a second via layer) may be disposed on the seventh insulating layer INS7. The eighth insulating layer INS8 may include the same material as the seventh insulating layer INS7, or may include one or more suitable (or selected) materials from among example materials listed as the constituent material of the seventh insulating layer INS7. For example, the eighth insulating layer INS8 may be an organic layer including an organic material.

The ninth insulating layer INS9 (or a third via layer) may be disposed on the eighth insulating layer INS8. The ninth insulating layer INS9 may include the same material as the seventh insulating layer INS7, or may include one or more suitable (or selected) materials from among example materials listed as the constituent material of the seventh insulating layer INS7. For example, the ninth insulating layer INS9 may be an organic layer including an organic material.

The pixel circuit layer PCL may include at least one or more conductive layers disposed between the above-mentioned insulating layers. For example, the conductive layers may include a first conductive layer CL1 disposed between the second insulating layer INS2 and the third insulating layer INS3, a second conductive layer CL2 disposed between the third insulating layer INS3 and the fourth insulating layer INS4, a third conductive layer CL3 disposed between the fifth insulating layer INS5 and the sixth insulating layer INS6, a fourth conductive layer CL4 disposed between the sixth insulating layer INS6 and the seventh insulating layer INS7, a fifth conductive layer CL5 disposed between the seventh insulating layer INS7 and the eighth insulating layer INS8, and a sixth conductive layer CL6 disposed between the eighth insulating layer INS8 and the ninth insulating layer INS9. However, the insulating layers and the conductive layers are not limited to the foregoing embodiment. In some embodiments, in addition to the insulating layers and the conductive layers mentioned above, other insulating layers and other conductive layers may be disposed in the pixel circuit layer PCL.

In one or more embodiments, a first semiconductor layer may be disposed between the first insulating layer INS1 and the second insulating layer INS2. The first semiconductor layer may include a silicon semiconductor. For example, the silicon semiconductor may include amorphous silicon, polycrystalline silicon, and/or the like. The first semiconductor layer includes low-temperature polysilicon, but is not limited thereto. The first semiconductor layer may include a first semiconductor area with high conductivity, and a second semiconductor area with low conductivity. The first semiconductor area may be doped with an N-type dopant or a P-type dopant. The P-type transistor may include a doping area doped with a P-type dopant. The N-type transistor may include a doping area doped with an N-type dopant. The second semiconductor area may be an undoped area or an area doped at a lower concentration compared to the first semiconductor area. The conductivity of the first semiconductor area may be greater than the conductivity of the second semiconductor area. The first semiconductor area may substantially function as an electrode or a signal line. The second semiconductor area may substantially correspond to an active pattern (or a channel area) of a transistor. A portion of the first semiconductor layer may be an active pattern area of the transistor. Another portion of the first semiconductor layer may be a source/drain area (or source/drain electrode) of the transistor. Another portion of the first semiconductor layer may be a connection electrode or a connection signal line. However, the present disclosure is not limited to the aforementioned example.

In one or more embodiments, a second semiconductor layer may be disposed between the fourth insulating layer INS4 and the fifth insulating layer INS5. The second semiconductor layer may include an oxide semiconductor. The oxide semiconductor may include a plurality of areas distinguished from each other depending on whether metal oxide has been reduced. An area where metal oxide has been reduced (hereinafter, referred to as “reduced area”) may have relatively high conductivity compared to an area where metal oxide has not been reduced (hereinafter, referred to as “unreduced area”). The reduced area may be substantially used as a source/drain area of the transistor or a signal line. The unreduced area may substantially correspond to the active pattern (or the channel area) of the transistor. A portion of the second semiconductor layer may be an active pattern of the transistor. Another portion of the second semiconductor layer may be a source/drain area (or source/drain electrode) of the transistor. Another portion of the second semiconductor layer may be a signal transmission area. However, the present disclosure is not limited to the aforementioned example.

The third transistor T3 and the sixth transistor T6 may be disposed in the pixel circuit layer PCL.

The sixth transistor T6 may include a gate electrode GE6 (hereinafter, referred to as “sixth gate electrode”), a first semiconductor pattern SCP1, a first terminal TE1, and a second terminal TE2. The third transistor T3 may include a gate electrode GE3 (hereinafter, referred to as “third gate electrode”), a second semiconductor pattern SCP2, a third terminal TE3, and a fourth terminal TE4.

The first semiconductor pattern SCP1 may be disposed on the first insulating layer INS1. The first semiconductor pattern SCP1 may be formed of the first semiconductor layer. The first semiconductor pattern SCP1 may include a channel area, a first contact area that contacts a first end of the channel area, and a second contact area that contacts a second end of the channel area. The second insulating layer INS2 may be disposed on the first semiconductor pattern SCP1.

The sixth gate electrode GE6 may correspond to the first conductive layer CL1 disposed on the second insulating layer INS2. The first conductive layer CL1 may be formed as a single-layer or multilayer structure formed of molybdenum, copper, chromium, gold, silver, titanium, nickel, neodymium, indium, tin, and/or an oxide and/or an alloy thereof. For example, the first conductive layer CL1 may be formed as a multiplayer structure formed by sequentially or repetitively stacking titanium, copper, and/or indium tin oxide, but is not limited thereto. The sixth gate electrode GE6 may overlap one area of the first semiconductor pattern SCP1 in a thickness direction of the substrate SUB (e.g., a third direction DR3). The one area of the first semiconductor pattern SCP1 that overlaps the sixth gate electrode GE6 may be the channel area of the sixth transistor T6. The third insulating layer INS3 may be disposed on the sixth gate electrode GE6.

The first terminal TE1 and the second terminal TE2 may be disposed on the sixth insulating layer INS6. The first terminal TE1 and the second terminal TE2 may be formed of the fourth conductive layer CL4. The fourth conductive layer CL4 may be formed as a single-layer or multilayer structure formed of molybdenum, copper, aluminum, chromium, gold, silver, titanium, nickel, neodymium, indium, tin, and/or an oxide and/or alloy thereof.

The first terminal TE1 may be electrically connected to the second contact area of the first semiconductor pattern SCP1 through a first contactor CNT1 passing through the second insulating layer INS2, the third insulating layer INS3, the fourth insulating layer INS4, the fifth insulating layer INS5, and the sixth insulating layer INS6. The first terminal TE1 may be electrically connected to an anode electrode AE of the light emitting element LD. The second terminal TE2 may be electrically connected to the first contact area of the first semiconductor pattern SCP1 through another first contactor CNT1 passing through the second insulating layer INS2, the third insulating layer INS3, the fourth insulating layer INS4, the fifth insulating layer INS5, and the sixth insulating layer INS6. The first terminal TE1 and the second terminal TE2 may be disposed on the sixth insulating layer INS6 at positions spaced from each other. The seventh insulating layer INS7 may be disposed on the first terminal TE1 and the second terminal TE2.

The second semiconductor pattern SCP2 may be disposed on the fourth insulating layer INS4. The second semiconductor pattern SCP2 may be formed of the second semiconductor layer. The second semiconductor pattern SCP2 may include a channel area, a first contact area that contacts a first end of the channel area, and a second contact area that contacts a second end of the channel area. The fifth insulating layer INS5 may be disposed on the second semiconductor pattern SCP2.

The third gate electrode GE3 may be disposed on the fifth insulating layer INS5. The third gate electrode GE3 may be formed of the third conductive layer CL3. The third conductive layer CL3 may include the same material as the first conductive layer CL1 and/or the fourth conductive layer CL4, or may include a suitable (or selected) material from among example materials listed as the constituent material of the first conductive layer CL1 and/or the fourth conductive layer CL4. The third gate electrode GE3 may overlap one area of the second semiconductor pattern SCP2. The one area of the second semiconductor pattern SCP2 that overlaps the third gate electrode GE3 may be the channel area of the third transistor T3.

The sixth insulating layer INS6 may be disposed on the third gate electrode GE3.

The third terminal TE3 and the fourth terminal TE4 may be disposed on the sixth insulating layer INS6. The third terminal TE3 and the fourth terminal TE4 may be formed of the fourth conductive layer CL4.

The third terminal TE3 may be electrically connected to the first contact area of the second semiconductor pattern SCP2 through a second contactor CNT2 passing through the fifth insulating layer INS5 and the sixth insulating layer INS6. The fourth terminal TE4 may be electrically connected to the second contact area of the second semiconductor pattern SCP2 through another second contactor CNT2 passing through the fifth insulating layer INS5 and the sixth insulating layer INS6. The third terminal TE3 and the fourth terminal TE4 may be disposed on the sixth insulating layer INS6 at positions spaced from each other. The seventh insulating layer INS7 may be disposed on the third terminal TE3 and the fourth terminal TE4.

The storage capacitor Cst may be disposed in the pixel circuit layer PCL. The storage capacitor Cst may include a lower electrode LE and an upper electrode UE.

The lower electrode LE may be disposed on the second insulating layer INS2. The lower electrode LE may be formed of the first conductive layer CL1 and may be provided in (or at) the same layer as the sixth gate electrode GE6, but is not limited thereto. The third insulating layer INS3 may be disposed on the lower electrode LE.

The upper electrode UE may be disposed on the third insulating layer INS3. The upper electrode UE may be formed of the second conductive layer CL2, but is not limited thereto. The second conductive layer CL2 may include the same material as the first conductive layer CL1 and/or the fourth conductive layer CL4, or may include one or more suitable (or selected) materials from among example materials listed as the constituent material of the first conductive layer CL1 and/or the fourth conductive layer CL4. The upper electrode UE may overlap the lower electrode LE in the third direction DR3 with the third insulating layer INS3 interposed therebetween, thus forming a capacitance.

A connection pattern CNP and a bridge pattern BRP may be disposed in the pixel circuit layer PCL.

The connection pattern CNP may be disposed on the seventh insulating layer INS7. The connection pattern CNP may be formed of the fifth conductive layer CL5. The fifth conductive layer CL5 may include the same material as the first conductive layer CL1 and/or the fourth conductive layer CL4, or may include one or more suitable (or selected) materials from among example materials listed as the constituent material of the first conductive layer CL1 and/or the fourth conductive layer CL4. The connection pattern CNP may be electrically connected to the first terminal TE1 of the sixth transistor T6 through a via hole VIH1 passing through the seventh insulating layer INS7. An eighth insulating layer INS8 may be disposed on the connection pattern CNP.

The bridge pattern BRP may be disposed on the eighth insulating layer INS8. The bridge pattern BRP may be formed of the sixth conductive layer CL6. The sixth conductive layer CL6 may include the same material as the first conductive layer CL1 and/or the fourth conductive layer CL4, or may include one or more suitable (or selected) materials from among example materials listed as the constituent material of the first conductive layer CL1 and/or the fourth conductive layer CL4. The bridge pattern BRP may be electrically connected to the connection pattern CNP via a second via hole VIH2 passing through the eighth insulating layer INS8. The ninth insulating layer INS9 may be disposed on the bridge pattern BRP.

The display element layer DPL may be disposed on the pixel circuit layer PCL.

The light emitting element LD and the bank BNK may be disposed in the display element layer DPL. The light emitting element LD may include an anode electrode AE (or a pixel electrode), an emission layer EML, and a cathode electrode CE (or a common electrode). The light emitting element LD may be electrically connected to the sixth transistor T6 through the bridge pattern BRP and the connection pattern CNP. The emission layer EML may include a hole transport layer, an organic material layer (or a light generation layer), and an electron transport layer.

The anode electrode AE may be disposed on the ninth insulating layer INS9. The anode electrode AE may be formed of a metal layer made of silver magnesium, aluminum, platinum, palladium, gold, nickel, neodymium, iridium, chrome, and/or an alloy thereof, and/or indium tin oxide (ITO), indium zinc oxide (IZO), zinc oxide (ZnO), indium tin zinc oxide (ITZO), and/or the like, but are not limited thereto. The anode electrode AE may be electrically connected to the bridge pattern BRP through a third via hole VIH3 passing through the ninth insulating layer INS9.

The bank BNK may be disposed on the ninth insulating layer INS9 in a non-emission area NEA of the sub-pixel SPX. The bank BNK may be a pixel defining layer that defines (or partitions) an emission area EMA of the sub-pixel SPX. The bank BNK may be an organic layer including an organic material (or substance). The organic material may include acryl resin, epoxy resin, phenolic resin, polyamide resin, polyimide resin, and/or the like.

In one or more embodiments, the bank BNK may include a light absorbing material and/or may be coated with a light absorbent, thus functioning to absorb light introduced from the outside. For example, the bank BNK may include carbon-based black pigment, but is not limited thereto. The bank BNK may include an opaque metallic material with high light absorption, such as chromium, molybdenum, an alloy of molybdenum and titanium, tungsten, vanadium, niobium, tantalum, manganese, cobalt, and/or nickel. The bank BNK may include an opening through which one area of the anode electrode AE is exposed. The opening of the bank BNK may correspond to the emission area EMA of the sub-pixel SPX.

The emission layer EML may be disposed on the anode electrode AE. The emission layer EML may include an organic emission layer. The emission layer EML may emit light such as red light, green light, or blue light depending on organic material included in the emission layer EML, but is not limited thereto.

The cathode electrode CE may be disposed on the emission layer EML. The cathode electrode CE may be a common electrode integrally formed in the display area DA. The cathode electrode CE may be supplied with the second power voltage VSS.

The cathode electrode CE may be formed of a metal layer made of Ag, Mg, Al, Pt, Pd, Au, Ni, Nd, Ir, Cr, and/or the like, and/or a transparent conductive layer made of ITO, IZO, ZnO, ITZO, and/or the like. In one or more embodiments, the cathode electrode CE may be formed as a multilayer structure including two or more layers. For example, the cathode electrode CE may be formed as a triple-layer structure made of ITO/Ag/ITO.

A thin-film encapsulation layer TFE may be disposed on the cathode electrode CE.

The thin-film encapsulation layer TFE may be formed of a single layer, or multi-layers. The thin-film encapsulation layer TFE may include a plurality of insulating layers configured to cover the light emitting element LD. In detail, the thin-film encapsulation layer TFE may include at least one inorganic layer and/or at least one organic layer. For example, the thin-film encapsulation layer TFE may have a structure formed by alternately stacking the inorganic layers and the organic layers.

The color filter layer CFL may be disposed on the thin-film encapsulation layer TFE. The color filter layer CFL may include a light blocking pattern and a color filter. The light blocking pattern may be disposed in the non-emission area NEA enclosing the emission area EMA of the sub-pixel SPX. The color filter may be disposed in the emission area EMA. The color filter layer CFL may be used as an anti-reflection layer to block external light reflection. The window WD may be disposed on the color filter layer CFL.

The window WD may protect an exposed surface of the display device DD. The window WD may protect the display device DD from external impact, and provide an input surface and/or a display surface to the user. The window WD (or a cover glass) may have a multilayer structure selected from among a glass substrate, a plastic film, and/or a plastic substrate. The multilayer structure may be formed through a successive process or an adhesion process using an adhesive layer. The window WD may entirely or partially have flexibility.

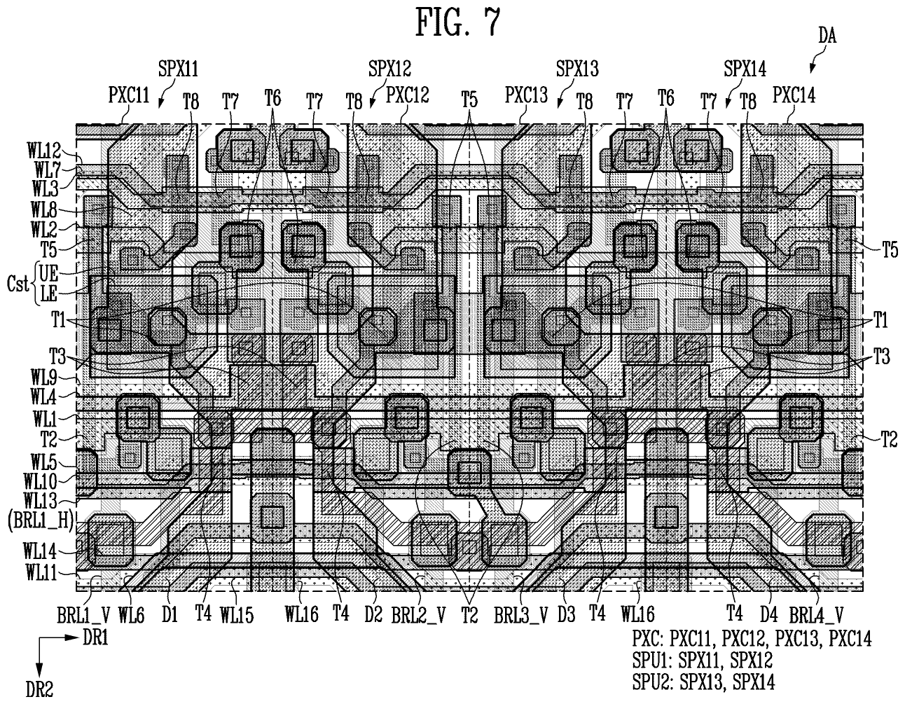

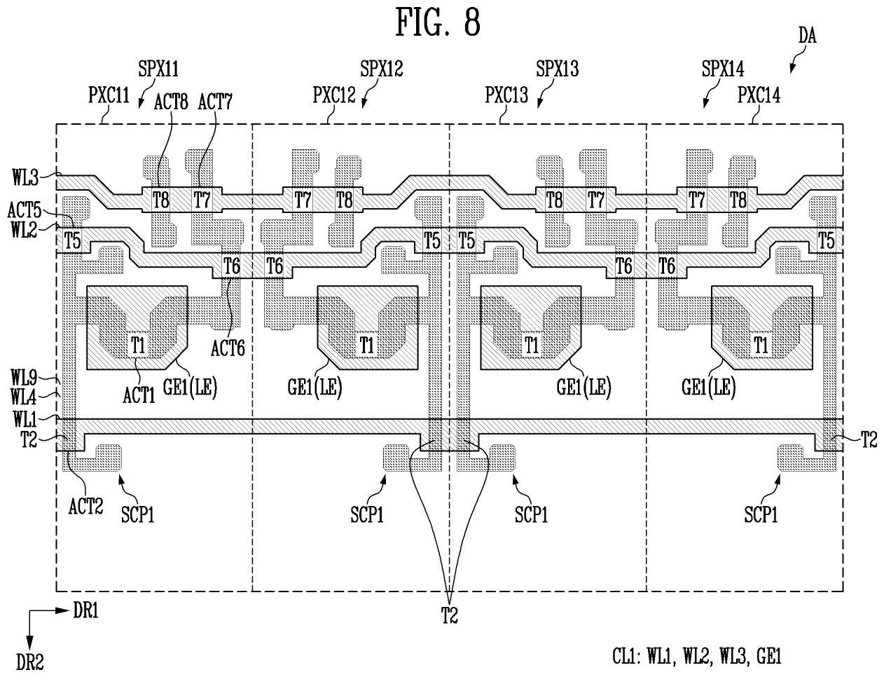

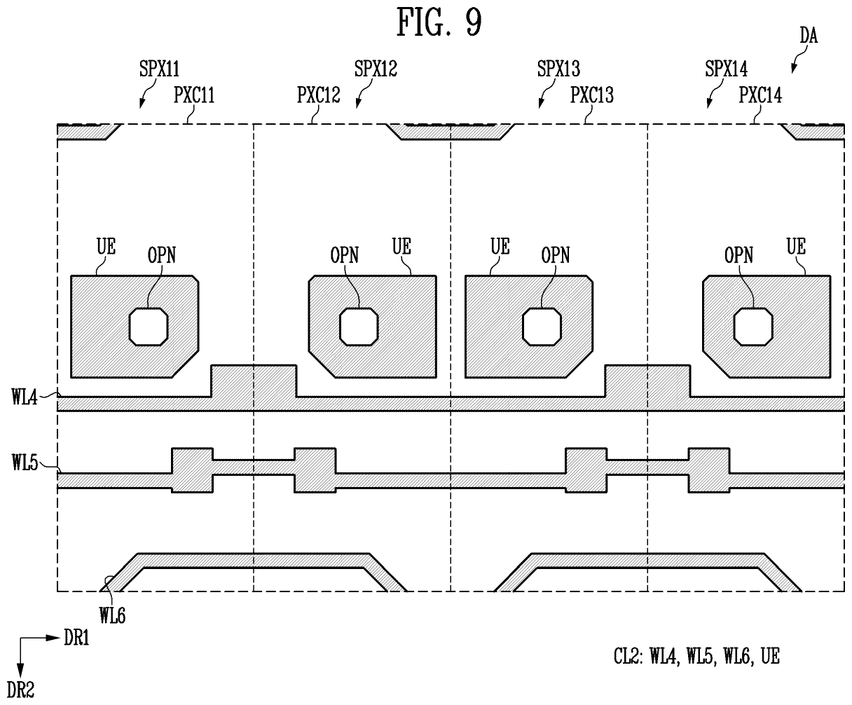

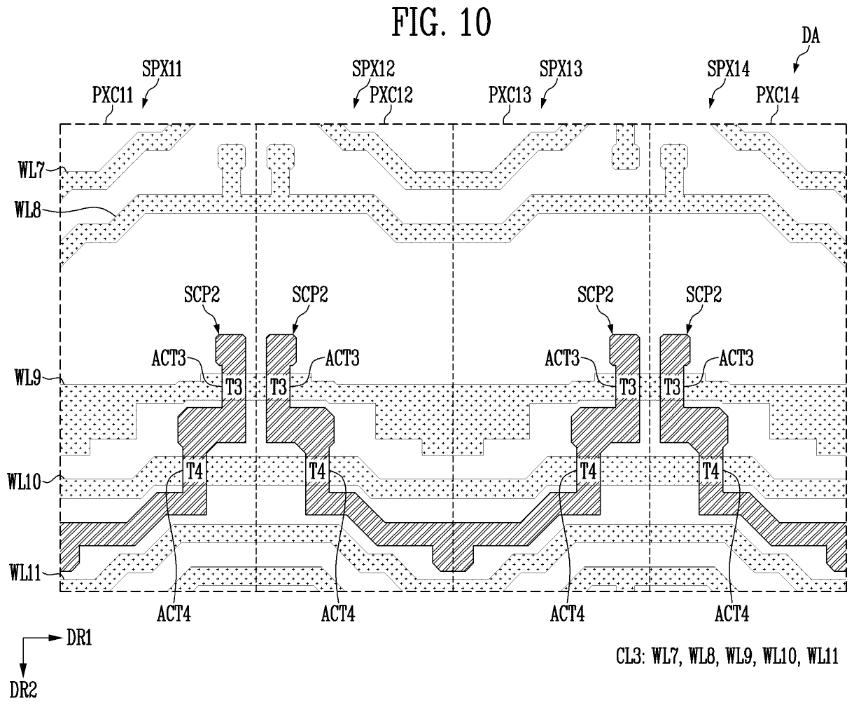

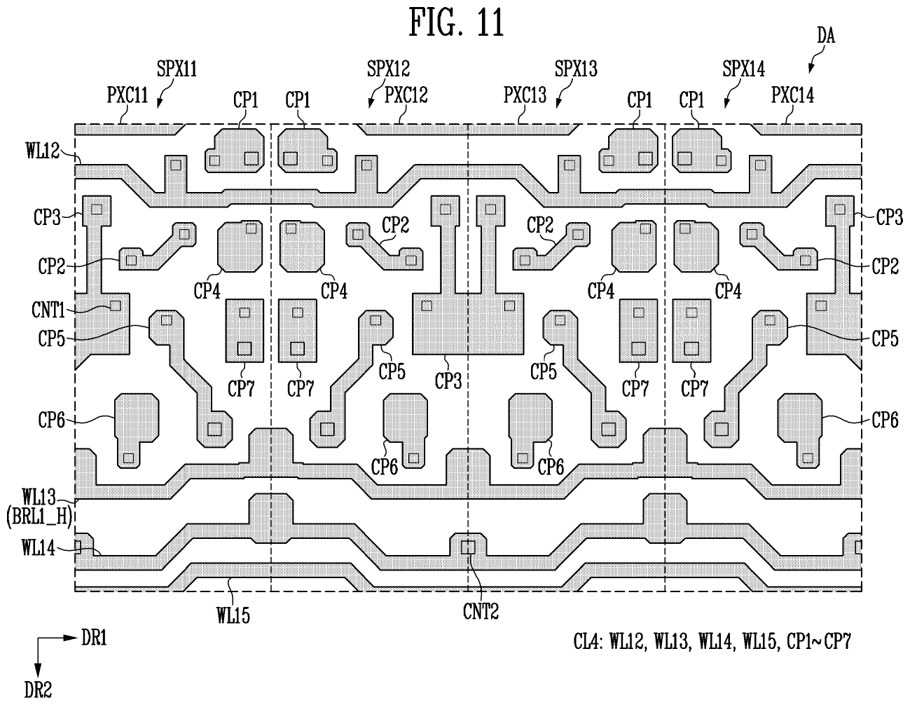

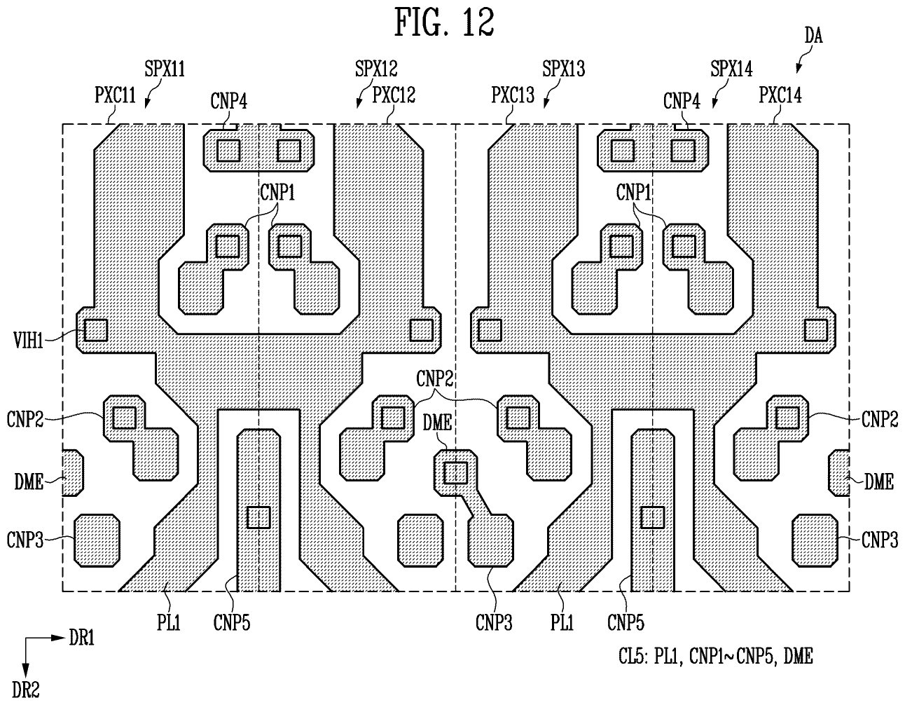

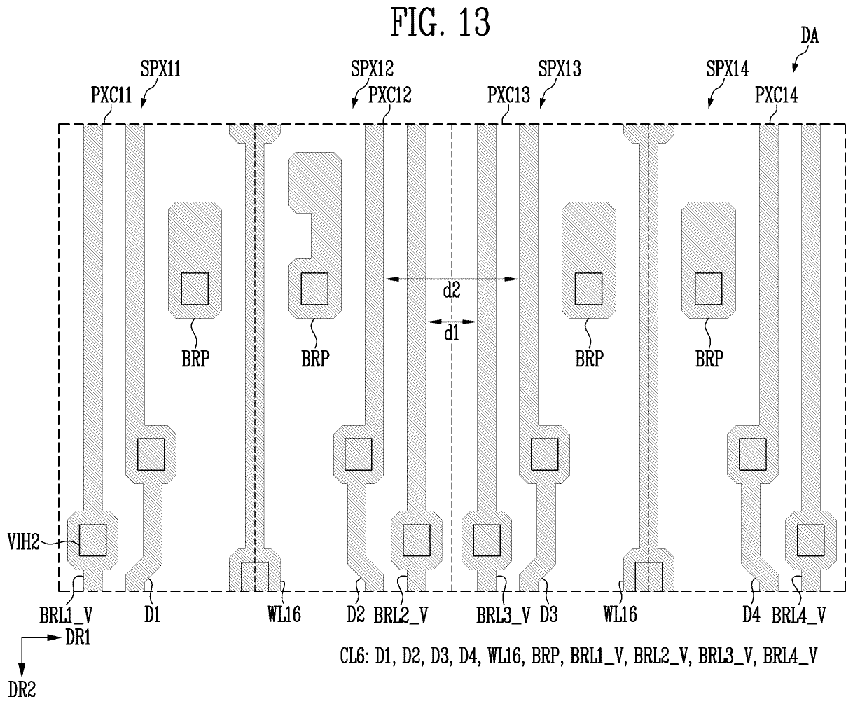

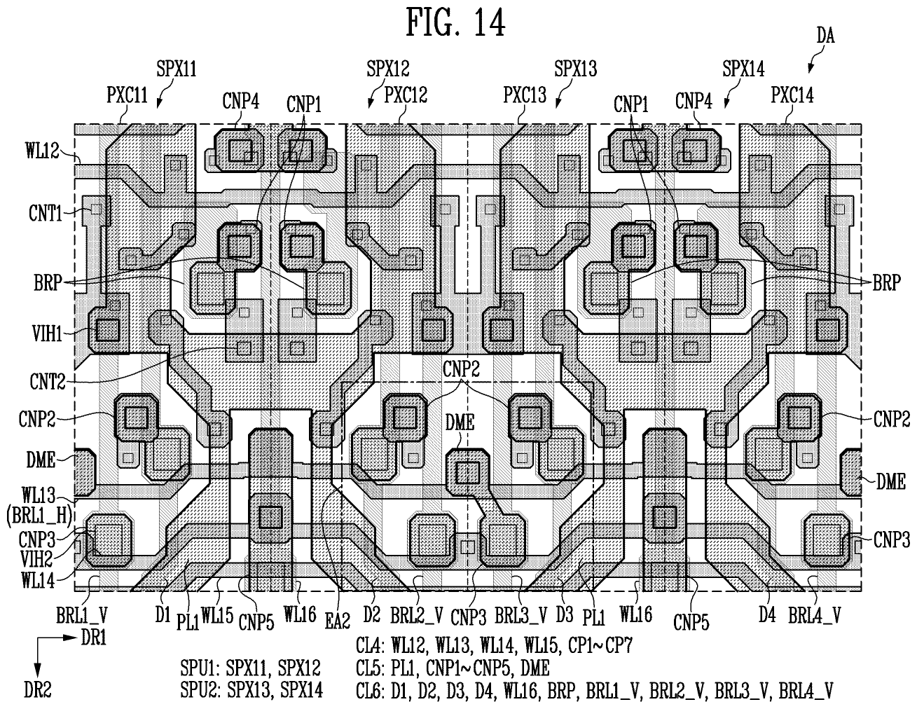

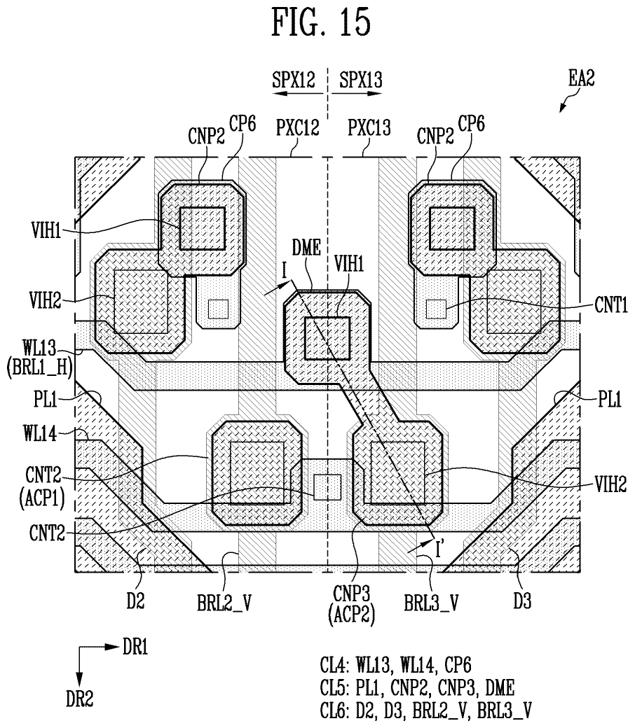

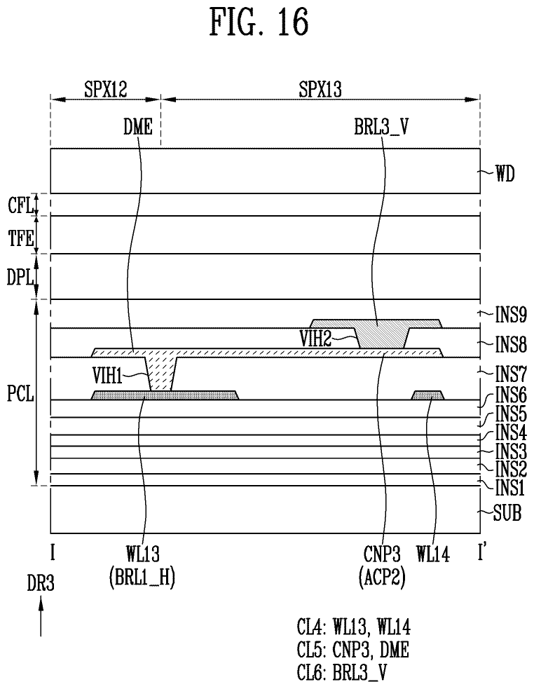

FIG. 7 is a schematic plan view illustrating sub-pixels positioned in one area of the display area DA of the display device in accordance with one or more embodiments. FIG. 8 is a schematic plan view illustrating only components included in the first, second, fifth, sixth, seventh, and eighth transistors T1, T2, T5, T6, T7, and T8 and the first conductive layer CL1 in FIG. 7. FIG. 9 is a schematic plan view illustrating only components included in the second conductive layer CL2 in FIG. 7. FIG. 10 is a schematic plan view illustrating only components included in the third and fourth transistors T3 and T4 and the third conductive layer CL3 in FIG. 7. FIG. 11 is a schematic plan view illustrating only components included in the fourth conductive layer CL4 in FIG. 7. FIG. 12 is a schematic plan view illustrating only components included in the fifth conductive layer CL5 in FIG. 7. FIG. 13 is a schematic plan view illustrating only components included in the sixth conductive layer CL6 in FIG. 7. FIG. 14 is a schematic plan view illustrating only components included in the fourth conductive layer CL4, the fifth conductive layer CL5, and the sixth conductive layer CL6 in FIG. 7. FIG. 15 is an enlarged schematic view showing a portion EA2 of FIG. 14. FIG. 16 is a schematic sectional view taken along the line I-I′ of FIG. 15.

For the sake of convenience in explanation, FIGS. 7-16 illustrate an 11-th sub-pixel SPX11, a 12-th sub-pixel SPX12, a 13-th sub-pixel SPX13, and a 14-th sub-pixel SPX14, which are arranged in the same pixel row (e.g., the first pixel row).

Referring to FIGS. 1-16, the 11-th sub-pixel SPX11 (or the first sub-pixel), the 12-th sub-pixel SPX12 (or the second sub-pixel), the 13-th sub-pixel SPX13 (or the third sub-pixel), and the 14-th sub-pixel SPX14 (or the fourth sub-pixel) may be arranged along the first direction DR1 in the display area (refer to “DA” in FIG. 2). In one or more embodiments, the 11-th sub-pixel SPX11 and the 14-th sub-pixel SPX14 may be red sub-pixels configured to emit red light. The 12-th sub-pixel SPX12 may be a green sub-pixel configured to emit green light. The 13-th sub-pixel SPX13 may be a blue sub-pixel configured to emit blue light. However, the present disclosure is not limited to the aforementioned example.

In one or more embodiments, the 11-th sub-pixel SPX11 and the 12-th sub-pixel SPX12 may form a first sub-pixel unit SPU1. The 13-th sub-pixel SPX13 and the 14-th sub-pixel SPX14 may form a second sub-pixel unit SPU2.

Each of the 11-th to 14-th sub-pixels SPX11 to SPX14 may include a pixel circuit PXC. For example, the 11-th sub-pixel SPX11 may include an 11-th pixel circuit PXC11. The 12-th sub-pixel SPX12 may include a 12-th pixel circuit PXC12. The 13-th sub-pixel SPX13 may include a 13-th pixel circuit PXC13. The 14-th sub-pixel SPX14 may include a 14-th pixel circuit PXC14.

Each of the 11-th to 14-th sub-pixels SPX11 to SPX14 may include a substrate SUB, a pixel circuit layer PCL, a display element layer DPL, a thin-film encapsulation layer TFE, a color filter layer CFL, and a window WD.

The substrate SUB may include transparent insulating material to allow light transmission. The substrate SUB may be a rigid substrate or a flexible substrate.

The 11-th to 14-th pixel circuits PXC11 to PXC14, and signal lines may be disposed in the pixel circuit layer PCL.

A light emitting element (refer to “LD” in FIG. 6) electrically connected to each of the 11-th to 14-th pixel circuits PXC11 to PXC14 may be disposed in the display element layer DPL.

The pixel circuit layer PCL may include a first insulating layer INS1, a second insulating layer INS2, a third insulating layer INS3, a fourth insulating layer INS4, a fifth insulating layer INS5, a sixth insulating layer INS6, a seventh insulating layer INS7, an eighth insulating layer INS8, and a ninth insulating layer INS9 that are sequentially stacked from the substrate SUB in the third direction DR3.

At least one or more conductive layers and at least one or more semiconductor layers may be disposed in the pixel circuit layer PCL. For example, the pixel circuit layer PCL may include a first semiconductor layer, a first conductive layer CL1, a second conductive layer CL2, a second semiconductor layer, a third conductive layer CL3, a fourth conductive layer CL4, a fifth conductive layer CL5, and a sixth conductive layer CL6 that are sequentially stacked from one surface of the substrate SUB in the third direction DR3.

Signal lines may be disposed in the display area DA in which the 11-th to 14-th sub-pixels SPX11 to SPX14 are positioned. For example, first to sixteenth lines WL1 to WL16, first to fourth data lines D1 to D4, a first power line PL1, and first to fourth vertical bridge lines BRL1_V to BRL4_V may be disposed in the display area DA.

The first line WL1 may extend in the first direction DR1, and may be formed of the first conductive layer CL1. The first line WL1 may be the 1i-th scan line S1i described with reference to FIG. 5. One area of the first line WL1 may be a gate electrode (hereinafter, referred to as “second gate electrode”) of the second transistor T2 of each of the 11-th to 14-th pixel circuits PXC11 to PXC14.

The second line WL2 may extend in the first direction DR1, and may be disposed to be spaced from the first line WL1. The second line WL2 may be formed of the first conductive layer CL1. The second line WL2 may be the i-th emission control line Ei described with reference to FIG. 5. One area of the second line WL2 may be a gate electrode (hereinafter, referred to as “fifth gate electrode”) of the fifth transistor T5 of each of the 11-th to 14-th pixel circuits PXC11 to PXC14. Furthermore, another area of the second line WL2 may be a gate electrode (hereinafter, referred to as “sixth gate electrode”) of the sixth transistor T6 of each of the 11-th to 14-th pixel circuits PXC11 to PXC14.

The third line WL3 may extend in the first direction DR1, and may be disposed to be spaced from the first and second lines WL1 and WL2. The third line WL3 may be formed of the first conductive layer CL1. In one or more embodiments, the third line WL3 may be the 3i-th scan line S3i described with reference to FIG. 5. One area of the third line WL3 may be a gate electrode (hereinafter, referred to as “seventh gate electrode”) of the seventh transistor T7 of each of the 11-th to 14-th pixel circuits PXC11 to PXC14. Another area of the third line WL3 may be a gate electrode (hereinafter, referred to as “eighth gate electrode”) of the eighth transistor T8 of each of the 11-th to 14-th pixel circuits PXC11 to PXC14.

The fourth line WL4 may extend in the first direction DR1, and may be formed of the second conductive layer CL2. The fourth line WL4 may be a dummy line overlapping the ninth line WL9 formed of the third conductive layer CL3, but is not limited thereto.

The fifth line WL5 may extend in the first direction DR1, and may be formed of the second conductive layer CL2. The fifth line WL5 may be disposed to be spaced from the fourth line WL4. The fifth line WL5 may be a dummy line overlapping the tenth line WL10 formed of the third conductive layer CL3, but is not limited thereto.

The sixth line WL6 may extend in the first direction DR1, and may be formed of the second conductive layer CL2. The sixth line WL6 may be disposed to be spaced from the fourth and fifth lines WL4 and WL5. The sixth line WL6 may be a dummy line overlapping the eleventh line WL11 formed of the third conductive layer CL3, but is not limited thereto.

The seventh line WL7 may extend in the first direction DR1, and may be formed of the third conductive layer CL3. The seventh line WL7 may be the third power line PL3 described with reference to FIG. 5 in each of the 11-th and 14-th sub-pixels SPX11 and SPX14. The seventh line WL7 may be supplied with the second initialization power voltage (refer to “Vint2” in FIG. 5). The seventh line WL7 may be electrically connected to the first semiconductor pattern SCP1 of the seventh transistor T7 of each of the 11-th and 14-th pixel circuits PXC11 and PXC14.

The eighth line WL8 may extend in the first direction DR1, and may be formed of the third conductive layer CL3. In one or more embodiments, the eighth line WL8 may be the third power line PL3 described with reference to FIG. 5 in each of the 12-th and 13-th sub-pixels SPX12 and SPX13. The eighth line WL8 may be supplied with the second initialization power voltage Vint2. The eighth line WL8 may be electrically connected to the first semiconductor pattern SCP1 of the seventh transistor T7 of each of the 12-th and 13-th pixel circuits PXC12 and PXC13.

The ninth line WL9 may extend in the first direction DR1, and may be formed of the third conductive layer CL3. The ninth line WL9 may be the 4i-th scan line S4i described with reference to FIG. 5. One area of the ninth line WL9 may be a gate electrode (hereinafter, referred to as “third gate electrode”) of the third transistor T3 of each of the 11-th to 14-th pixel circuits PXC11 to PXC14.

The tenth line WL10 may extend in the first direction DR1, and may be formed of the third conductive layer CL3. The tenth line WL10 may be the 2i-th scan line S2i described with reference to FIG. 5. One area of the tenth line WL10 may be the gate electrode (hereinafter, referred to as “fourth gate electrode”) of the fourth transistor T4 of each of the 11-th to 14-th pixel circuits PXC11 to PXC14.

The eleventh line WL11 may extend in the first direction DR1, and may be formed of the third conductive layer CL3. The eleventh line WL11 may be a dummy line overlapping the fourteenth line WL14 formed of the fourth conductive layer CL4, but is not limited thereto.

The twelfth line WL12 may extend in the first direction DR1, and may be formed of the fourth conductive layer CL4. The twelfth line WL12 may be the fourth power line PL4 described with reference to FIG. 5. The twelfth line WL12 may be supplied with a bias voltage (refer to “VOBS” in FIG. 5). The twelfth line WL12 may be electrically connected to the first semiconductor pattern SCP1 of the eighth transistor T8 of each of the 11-th to 14-th pixel circuits PXC11 to PXC14.

The thirteenth line WL13 may extend in the first direction DR1 and be disposed to be spaced from the twelfth line WL12. The thirteenth line WL13 may be formed of the fourth conductive layer CL4. The thirteenth line WL13 may be a first horizontal bridge line BRL1_H. The thirteenth line WL13 may be electrically connected to a corresponding data line from among the data lines positioned in the first area (refer to “DA1” in FIG. 2) of the display area DA.

The fourteenth line WL14 may extend in the first direction DR1 and be disposed to be spaced from the twelfth and thirteenth lines WL12 and WL13. The fourteenth line WL14 may be formed of the fourth conductive layer CL4. The fourteenth line WL14 may be the second power line PL2 described with reference to FIG. 5. The fourteenth line WL14 may be supplied with the first initialization power voltage (refer to “Vint1” in FIG. 5). The fourteenth line WL14 may be electrically connected to the second semiconductor pattern SCP2 of the fourth transistor T4 of each of the 11-th to 14-th pixel circuits PXC11 to PXC14.

The fifteenth line WL15 may extend in the first direction DR1, and may be disposed to be spaced from the twelfth and fourteenth lines WL12 and WL14. The fifteenth line WL15 may be formed of the fourth conductive layer CL4.

The sixteenth line WL16 may extend in the second direction DR2, and may be formed of the sixth conductive layer CL6. The sixteenth line WL16 may be disposed between two adjacent sub-pixels. For example, the sixteenth line WL16 may be disposed in each of areas between the 11-th sub-pixel SPX11 and the 12-th sub-pixel SPX12, and between the 13-th sub-pixel SPX13 and the 14-th sub-pixel SPX14. The sixteenth line WL16 may be electrically connected to a fifth connection pattern CNP5 of each of the 11-th to 14-th sub-pixels SPX11 to SPX14 through a second via hole VIH2 passing through the eighth insulating layer INS8.

The fifth connection pattern CNP5 may be formed of the fifth conductive layer CL5. In each of the 11-th to 14-th sub-pixels SPX11 to SPX14, the fifth connection pattern CNP5 may be electrically connected to the sixteenth line WL16 through the corresponding second via hole VIH2. Furthermore, the fifth connection pattern CNP5 may be electrically connected to the fourteenth line WL14 through a first via hole VIH1 passing through the seventh insulating layer INS7.

In each of the 11-th to 14-th sub-pixels SPX11 to SPX14, the first initialization power voltage Vint1 may be applied to the fourteenth line WL14 and the sixteenth line WL16 that are electrically connected by the fifth connection pattern CNP5. In one or more embodiments, the fourteenth line WL14 may be a horizontal power line of the second power line PL2. The sixteenth line WL16 may be a vertical power line of the second power line PL2. The second power line PL2 may have a mesh structure due to the fourteenth line WL14 and the sixteenth line WL16 that are electrically connected to each other.

The first data line D1 may extend in the second direction DR2, and may be formed of the sixth conductive layer CL6. The first data line D1 may be disposed in (or at) the same layer as the sixteenth line WL16, and may be disposed to be spaced from the sixteenth line WL16. The first data line D1 may be the j-th data line Dj described with reference to FIG. 5. The first data line D1 may be electrically connected to the first semiconductor pattern SCP1 of the second transistor T2 of the 11-th pixel circuit PXC11.

The second data line D2 may extend in the second direction DR2, and may be formed of the sixth conductive layer CL6. The second data line D2 may be disposed in (or at) the same layer as the first data line D1, and may be disposed to be spaced from the first data line D1. The second data line D2 may be the j-th data line Dj described with reference to FIG. 5. The second data line D2 may be electrically connected to the first semiconductor pattern SCP1 of the second transistor T2 of the 12-th pixel circuit PXC12.

The third data line D3 may extend in the second direction DR2, and may be formed of the sixth conductive layer CL6. The third data line D3 may be disposed in (or at) the same layer as the first and second data lines D1 and D2, and may be disposed to be spaced from the first and second data lines D1 and D2. The third data line D3 may be electrically connected to the first semiconductor pattern SCP1 of the second transistor T2 of the 13-th pixel circuit PXC13.

The fourth data line D4 may extend in the second direction DR2, and may be formed of the sixth conductive layer CL6. The fourth data line D4 may be disposed in (or at) the same layer as the first to third data lines D1 to D3, and may be disposed to be spaced from the first to third data lines D1 to D3. The fourth data line D4 may be electrically connected to the first semiconductor pattern SCP1 of the second transistor T2 of the 14-th pixel circuit PXC14.

The first vertical bridge line BRL1_V may extend in the second direction DR2, and may be formed of the sixth conductive layer CL6. The first vertical bridge line BRL1_V may be disposed in (or at) the same layer as the first to fourth data lines D1 to D4, and may be disposed to be spaced from the first to fourth data lines D1 to D4. The first vertical bridge line BRL1_V may overlap some components of the 11-th pixel circuit PXC11. The first vertical bridge line BRL1_V may be positioned on one side (e.g., a left side) of the first data line D1 in the 11-th sub-pixel SPX11, in a plan view. The first vertical bridge line BRL1_V may be positioned outside the first data line D1 in the 11-th sub-pixel SPX11 based on a boundary between two sub-pixels adjacent to each other in the first direction DR1, for example, the 11-th sub-pixel SPX11 and the 12-th sub-pixel SPX12.

The first vertical bridge line BRL1_V may be electrically connected to a corresponding one of the data lines positioned in the first area DA1. The first vertical bridge line BRL1_V may electrically connect the data line to a fan-out line positioned in the fan-out area (refer to “FTA” in FIG. 2) of the non-display area (refer to “NDA” in FIG. 2). Furthermore, the first vertical bridge line BRL1_V may be electrically connected to a third connection pattern CNP3 of the 11-th sub-pixel SPX11 through a second via hole VIH2 passing through the eighth insulating layer INS8.

The second vertical bridge line BRL2_V may extend in the second direction DR2, and may be disposed to be spaced from the first vertical bridge line BRL1_V. The second vertical bridge line BRL2_V may be formed of the sixth conductive layer CL6. The second vertical bridge line BRL2_V may overlap some components of the 12-th pixel circuit PXC12. The second vertical bridge line BRL2_V may be positioned on one side (e.g., a right side) of the second data line D2 in the 12-th sub-pixel SPX12, in a plan view. The second vertical bridge line BRL2_V may be positioned inside the second data line D2 in the 12-th sub-pixel SPX12 based on a boundary between two sub-pixels adjacent to each other in the first direction DR1, for example, the 12-th sub-pixel SPX12 and the 13-th sub-pixel SPX13. Furthermore, the second vertical bridge line BRL2_V may be positioned outside the second data line D2 in the 12-th sub-pixel SPX12 based on a boundary between two sub-pixels adjacent to each other in a direction opposite to the first direction DR1, for example, the 12-th sub-pixel SPX12 and the 11-th sub-pixel SPX11.

The second vertical bridge line BRL2_V may be electrically connected to a corresponding one of the data lines positioned in the first area DA1. The second vertical bridge line BRL2_V may electrically connect the data line to a fan-out line positioned in the fan-out area FTA. Furthermore, the second vertical bridge line BRL2_V may be electrically connected to a third connection pattern CNP3 of the 12-th sub-pixel SPX12 through a second via hole VIH2 passing through the eighth insulating layer INS8.

The third vertical bridge line BRL3_V may extend in the second direction DR2, and may be disposed to be spaced from the second vertical bridge line BRL2_V. The third vertical bridge line BRL3_V may be formed of the sixth conductive layer CL6. The third vertical bridge line BRL3_V may overlap some components of the 13-th pixel circuit PXC13. The third vertical bridge line BRL3_V may be positioned on one side (e.g., a left side) of the third data line D3 in the 13-th sub-pixel SPX13, in a plan view. The third vertical bridge line BRL3_V may be positioned outside the third data line D3 based on a boundary between two sub-pixels adjacent to each other in the first direction DR1, for example, the 13-th sub-pixel SPX13 and the 14-th sub-pixel SPX14. Furthermore, the third vertical bridge line BRL3_V may be positioned inside the third data line D3 based on a boundary between two sub-pixels adjacent to each other in the direction opposite to the first direction DR1, for example, the 13-th sub-pixel SPX13 and the 12-th sub-pixel SPX12.

The third vertical bridge line BRL3_V may be electrically connected to a corresponding one of the data lines positioned in the first area DA1. The third vertical bridge line BRL3_V may electrically connect the data line to a fan-out line positioned in the fan-out area FTA. Furthermore, the third vertical bridge line BRL3_V may be electrically connected to a third connection pattern CNP3 of the 13-th sub-pixel SPX13 through a second via hole VIH2 passing through the eighth insulating layer INS8.

The fourth vertical bridge line BRL4_V may extend in the second direction DR2, and may be disposed to be spaced from the third vertical bridge line BRL3_V. The fourth vertical bridge line BRL4_V may be formed of the sixth conductive layer CL6. The fourth vertical bridge line BRL4_V may be positioned on one side (e.g., a right side) of the fourth data line D4 in the 14-th sub-pixel SPX14, in a plan view. The fourth vertical bridge line BRL4_V may be positioned inside the fourth data line D4 based on a boundary between two sub-pixels adjacent to each other in the direction opposite to the first direction DR1, for example, the 14-th sub-pixel SPX14 and the 13-th sub-pixel SPX13.

The fourth vertical bridge line BRL4_V may be electrically connected to a corresponding one of the data lines positioned in the first area DA1. The fourth vertical bridge line BRL4_V may electrically connect the data line to a fan-out line positioned in the fan-out area FTA of the non-display area NDA. Furthermore, the fourth vertical bridge line BRL4_V may be electrically connected to a third connection pattern CNP3 of the 14-th sub-pixel SPX14 through a second via hole VIH2 passing through the eighth insulating layer INS8.

In each of the 11-th to 14-th sub-pixels SPX11 to SPX14, the third connection pattern CNP3 may be formed of the fifth conductive layer CL5, and may be electrically connected to the vertical bridge line through the corresponding second via hole VIH2. For example, the third connection pattern CNP3 of the 11-th sub-pixel SPX11 may be electrically connected to the first vertical bridge line BRL1_V through the corresponding second via hole VIH2. The third connection pattern CNP3 of the 12-th sub-pixel SPX12 may be electrically connected to the second vertical bridge line BRL2_V through the corresponding second via hole VIH2. The third connection pattern CNP3 of the 13-th sub-pixel SPX13 may be electrically connected to the third vertical bridge line BRL3_V through the corresponding second via hole VIH2. The third connection pattern CNP3 of the 14-th sub-pixel SPX14 may be electrically connected to the fourth vertical bridge line BRL4_V through the corresponding second via hole VIH2. The third connection pattern CNP3 may be an island-shaped conductive pattern.

In one or more embodiments, the third connection pattern CNP3 of the 13-th sub-pixel SPX13 may be electrically and/or physically connected to a dummy electrode DME.

The dummy electrode DME may be formed of the fifth conductive layer CL5 and may be positioned on a boundary portion between the first sub-pixel unit SPU1 and the second sub-pixel unit SPU2 (or a boundary portion between the 12-th sub-pixel SPX12 and the 13-th sub-pixel SPX13). The dummy electrode DME may be integrally formed with the third connection pattern CNP3 of the 13-th sub-pixel SPX13. In this case, the dummy electrode DME may be regarded as one area of the third connection pattern CNP3 of the 13-th sub-pixel SPX13. The dummy electrode DME may be electrically connected to the third vertical bridge line BRL3_V through the third connection pattern CNP3 of the 13-th sub-pixel SPX13. Furthermore, the dummy electrode DME may be electrically connected to the first horizontal bridge line BRL1_H through a first via hole VIH1 passing through the seventh insulating layer INS7.

The first data line D1, the second data line D2, the third data line D3, the fourth data line D4, the first vertical bridge line BRL1_V, the second vertical bridge line BRL2_V, the third vertical bridge line BRL3_V, and the fourth vertical bridge line BRL4_V described above may be formed through the same process, may include the same material, and may be disposed in (or at) the same layer.

The first power line PL1 may extend in the second direction DR2, and may be formed of the fifth conductive layer CL5. The first power line PL1 may be the first power line PL1 described with reference to FIG. 5. The first power line PL1 may be supplied with a first power voltage VDD. The 11-th sub-pixel SPX11 and the 12-th sub-pixel SPX12 may share one first power line PL1. The 13-th sub-pixel SPX13 and the 14-th sub-pixel SPX14 may share one first power line PL1. However, the present disclosure is not limited to the aforementioned example.

In each of the 11-th to 14-th sub-pixels SPX11 to SPX14, the first power line PL1 may be electrically connected to a third conductive pattern CP3 formed of the fourth conductive layer CL4 through a first via hole VIH1 passing through the seventh insulating layer INS7.

The third conductive pattern CP3 may be formed of the fourth conductive layer CL4, and may be electrically connected to the first power line PL1 through a corresponding first via hole VIH1. Furthermore, the third conductive pattern CP3 may be electrically connected to the first semiconductor pattern SCP1 of the fifth transistor T5 of each of the 11-th to 14-th pixel circuits PXC11 to PXC14 through a corresponding first contactor CNT1 passing through the sixth insulating layer INS6, the fifth insulating layer INS5, the fourth insulating layer INS4, the third insulating layer INS3, and the second insulating layer INS2. In one or more embodiments, the first power line PL1 formed of the fifth conductive layer CL5 may be electrically connected to the first semiconductor pattern SCP1 of the fifth transistor T5 formed of the first semiconductor layer through the third conductive pattern CP3 formed of the fourth conductive layer CL4. Furthermore, the third conductive pattern CP3 may be electrically connected to the upper electrode UE formed of the second conductive layer CL2 through a corresponding first contactor CNT1 passing through the sixth insulating layer INS6, the fifth insulating layer INS5, and the fourth insulating layer INS4.

The 11-th pixel circuit PXC11, the 12-th pixel circuit PXC12, the 13-th pixel circuit PXC13, and the 14-th pixel circuit PXC14 may have a substantially similar or identical structure. For example, the 11-th pixel circuit PXC11 and the 12-th pixel circuit PXC12 that are included in the first sub-pixel unit SPU1 and the 13-th pixel circuit PXC13 and the 14-th pixel circuit PXC14 that are included in the second sub-pixel unit SPU2 may be symmetric to each other. In one or more embodiments, the 11-th pixel circuit PXC11 and the 12-th pixel circuit PXC12 may form a mirror symmetry with respect to the boundary between the 11-th pixel circuit PXC11 and the 12-th pixel circuit PXC12. The 13-th pixel circuit PXC13 and the 14-th pixel circuit PXC14 may form a mirror symmetry with respect to the boundary between the 13-th sub-pixel SPX13 and the 14-th sub-pixel SPX14. However, the present disclosure is not limited to the aforementioned example.

Hereinafter, for the sake of convenience in explanation, the following description will be centered on the 11-th pixel circuit PXC11, and redundant explanations will be omitted.

The 11-th pixel circuit PXC11 may include first, second, third, fourth, fifth, sixth, seventh, and eighth transistors T1, T2, T3, T4, T5, T6, T7, and T8 and a storage capacitor Cst.

The first transistor T1 may include a first active pattern ACT1 and a first gate electrode GE1.

The first active pattern ACT1 may be one area of the first semiconductor pattern SCP1 overlapping the first gate electrode GE1. The first semiconductor pattern SCP1 may correspond to the first semiconductor layer. The first active pattern ACT1 may be a channel area of the first transistor T1.

For example, the channel area may be an undoped semiconductor pattern, and may be an intrinsic semiconductor. The other area of the semiconductor pattern except the channel area may be a semiconductor pattern doped with impurities.

One area of the first semiconductor pattern SCP1 connected to one side (e.g., a left side of the first active pattern ACT1 in a plan view) of the first active pattern ACT1 (or the channel area) without overlapping the first gate electrode GE1 may be a first contact area. One area of the first semiconductor pattern SCP1 connected to another side (e.g., a right side of the first active pattern ACT1 in a plan view) of the first active pattern ACT1 without overlapping the first gate electrode GE1 may be a second contact area. The first contact area and the second contact area may extend in opposite directions from the first active pattern ACT1 (or the channel area). The first contact area and the second contact area may face each other in the first direction DR1 with the first active pattern ACT1 interposed therebetween.

The first contact area may be connected to the first side of the first active pattern ACT1 and connected both to the first semiconductor pattern SCP1 of the second transistor T2 and the first semiconductor pattern SCP1 of the fifth transistor T5. The second contact area may be connected to the second side of the first active pattern ACT1, and connected to the first semiconductor pattern SCP1 of the sixth transistor T6.

The first gate electrode GE1 may overlap the first active pattern ACT1, and may be formed of the first conductive layer CL1. The first gate electrode GE1 may be an island-shaped conductive pattern. The first gate electrode GE1 may be electrically connected to the third transistor T3 and the fourth transistor T4 through a fifth conductive pattern CP5.

The fifth conductive pattern CP5 may be formed of the fourth conductive layer CL4. A first end of the fifth conductive pattern CP5 may be electrically connected to the first gate electrode GE1 through a corresponding first contactor CNT1 passing through the sixth insulating layer INS6, the fifth insulating layer INS5, the fourth insulating layer INS4, and the third insulating layer INS3. A second end of the fifth conductive pattern CP5 may be electrically connected to one area of the second semiconductor pattern SCP2 shared by the third transistor T3 and the fourth transistor T4 through a second contactor CNT2 passing through the sixth insulating layer INS6 and the fifth insulating layer INS5.

The second transistor T2 may include a second active pattern ACT2 and a second gate electrode.

The second active pattern ACT2 may be one area of the first semiconductor pattern SCP1 overlapping the first line WL1. The first semiconductor pattern SCP1 may be formed of the first semiconductor layer. The second active pattern ACT2 may be a channel area of the second transistor T2.

One area of the first semiconductor pattern SCP1 connected to a first side (e.g., a lower side of the second active pattern ACT2 in a plan view) of the second active pattern ACT2 without overlapping the first line WL1 may be a first contact area. One area of the first semiconductor pattern SCP1 connected to a second side (e.g., an upper side of the second active pattern ACT2 in a plan view) of the second active pattern ACT2 without overlapping the first line WL1 may be a second contact area. The first contact area may be connected to the first side of the second active pattern ACT2, and electrically connected to a sixth conductive pattern CP6. The second contact area may be connected to the second side of the second active pattern ACT2, and connected to the first contact area of the first transistor T1.

The sixth conductive pattern CP6 may be formed of the fourth conductive layer CL4. The sixth conductive pattern CP6 may be electrically connected to the first semiconductor pattern SCP1 corresponding to the first contact area of the second transistor T2 through a first contactor CNT1 passing through the sixth insulating layer INS6, the fifth insulating layer INS5, the fourth insulating layer INS4, the third insulating layer INS3, and the second insulating layer INS2. Furthermore, the sixth conductive pattern CP6 may be electrically connected to a second connection pattern CNP2 through a first via hole VIH1.

The second connection pattern CNP2 may be formed of the fifth conductive layer CL5, and may be electrically connected to the sixth conductive pattern CP6 through the corresponding first via hole VIH1 passing through the seventh insulating layer INS7. Furthermore, the second connection pattern CNP2 may be electrically connected to the first data line D1 formed of the sixth conductive layer CL6 through a second via hole VIH2 passing through the eighth insulating layer INS8.

The first contact area of the first semiconductor pattern SCP1 of the second transistor T2 may be electrically connected to the first data line D1 through the sixth conductive pattern CP6 and the second connection pattern CNP2.

The second gate electrode may be one area of the first line WL1 overlapping the second active pattern ACT2.

The third transistor T3 may include a third active pattern ACT3 and a third gate electrode.

The third active pattern ACT3 may be one area of the second semiconductor pattern SCP2 overlapping the ninth line WL9, and form a channel area of the third transistor T3. The second semiconductor pattern SCP2 may be formed of the second semiconductor layer.

One area of the second semiconductor pattern SCP2 connected to a first side (e.g., an upper side of the third active pattern ACT3 in a plan view) of the third active pattern ACT3 without overlapping the ninth line WL9 may be a first contact area. One area of the second semiconductor pattern SCP2 connected to a second side (e.g., a lower side of the third active pattern ACT3 in a plan view) of the third active pattern ACT3 without overlapping the ninth line WL9 may be a second contact area. The first contact area may be connected to the first side of the third active pattern ACT3, and may be electrically connected to the first transistor T1 and the sixth transistor T6 through a seventh conductive pattern CP7. The second contact area may be connected to the second side of the third active pattern ACT3, and may be connected to the second semiconductor pattern SCP2 of the fourth transistor T4.

The seventh conductive pattern CP7 may be formed of the fourth conductive layer CL4. A first end of the seventh conductive pattern CP7 may be electrically connected to the first contact area of the third transistor T3 through a second contactor CNT2 passing through the sixth insulating layer INS6 and the fifth insulating layer INS5. A second end of the seventh conductive pattern CP7 may be electrically connected to one area of the first semiconductor pattern SCP1 that is shared by the first transistor T1 and the sixth transistor T6 through a first contactor CNT1 passing through the sixth insulating layer INS6, the fifth insulating layer INS5, the fourth insulating layer INS4, the third insulating layer INS3, and the second insulating layer INS2.

The third gate electrode may be one area of the ninth line WL9 overlapping the third active pattern ACT3.

The fourth transistor T4 may include a fourth active pattern ACT4 and a fourth gate electrode.

The fourth active pattern ACT4 may be one area of the second semiconductor pattern SCP2 overlapping the tenth line WL10, and may form a channel area of the fourth transistor T4. The second semiconductor pattern SCP2 may be formed of the second semiconductor layer.

One area of the second semiconductor pattern SCP2 connected to a first side (e.g., an upper side of the fourth active pattern ACT4 in a plan view) of the fourth active pattern ACT4 without overlapping the tenth line WL10 may be a first contact area. One area of the second semiconductor pattern SCP2 connected to a second side (e.g., a lower side of the fourth active pattern ACT4 in a plan view) of the fourth active pattern ACT4 without overlapping the tenth line WL10 may may be a second contact area. The first contact area may be connected to the first side of the fourth active pattern ACT4, and may be connected to the second semiconductor pattern SCP2 of the third transistor T3. The second contact area may be connected to the second side of the fourth active pattern ACT4, and may be electrically connected to the fourteenth line WL14 formed of the fourth conductive layer CL4 through a corresponding second contactor CNT2 passing through the sixth insulating layer INS6 and the fifth insulating layer INS5.

The fourth gate electrode may be one area of the tenth line WL10 overlapping the fourth active pattern ACT4.

The fifth transistor T5 may include a fifth active pattern ACT5 and a fifth gate electrode.

The fifth active pattern ACT5 may be one area of the first semiconductor pattern SCP1 overlapping the second line WL2, and may form a channel area of the fifth transistor T5. The first semiconductor pattern SCP1 may be formed of the first semiconductor layer.

One area of the first semiconductor pattern SCP1 connected to a first side (e.g., an upper side of the fifth active pattern ACT5 in a plan view) of the fifth active pattern ACT5 without overlapping the second line WL2 may be a first contact area. One area of the first semiconductor pattern SCP1 connected to a second side (e.g., a lower side of the fifth active pattern ACT5 in a plan view) of the fifth active pattern ACT5 without overlapping the second line WL2 may be a second contact area. The first contact area may be connected to the first side of the fifth active pattern ACT5, and may be electrically connected to the third conductive pattern CP3 through a corresponding first contactor CNT1. The second contact area may be connected to the second side of the fifth active pattern ACT5, and may be connected to the first semiconductor pattern SCP1 of each of the first and second transistors T1 and T2.

The fifth gate electrode may be one area of the second line WL2 overlapping the fifth active pattern ACT5.

The sixth transistor T6 may include a sixth active pattern ACT6 and a sixth gate electrode.

The sixth active pattern ACT6 may be one area of the first semiconductor pattern SCP1 overlapping the second line WL2, and may be a channel area of the sixth transistor T6. The first semiconductor pattern SCP1 may be formed of the first semiconductor layer.

One area of the first semiconductor pattern SCP1 connected to a first side (e.g., an upper side of the sixth active pattern ACT6 in a plan view) of the sixth active pattern ACT6 without overlapping the second line WL2 may be a first contact area. One area of the first semiconductor pattern SCP1 connected to a second side (e.g., a lower side of the sixth active pattern ACT6 in a plan view) of the sixth active pattern ACT6 without overlapping the second line WL2 may be a second contact area. The first contact area may be connected to each of the first side of the sixth active pattern ACT6 and the first semiconductor pattern SCP1 of the seventh transistor T7. The second contact area may be connected to each of the second side of the sixth active pattern ACT6 and the first semiconductor pattern SCP1 of the first transistor T1. Furthermore, the second contact area may be electrically connected to a fourth conductive pattern CP4 through a corresponding first contactor CTN1.

The fourth conductive pattern CP4 may be formed of the fourth conductive layer CL4. The fourth conductive pattern CP4 may be electrically connected to the second contact area of the sixth transistor T6 through a corresponding first contactor CNT1 passing through the sixth insulating layer INS6, the fifth insulating layer INS5, the fourth insulating layer INS4, the third insulating layer INS3, and the second insulating layer INS2. Furthermore, the fourth conductive pattern CP4 may be electrically connected to a first connection pattern CNP1 formed of the fifth conductive layer CL5 through a corresponding first via hole VIH1.

A first end of the first connection pattern CNP1 may be electrically connected to the fourth conductive pattern CP4 through a corresponding first via hole VIH1 passing through the seventh insulating layer INS7. A second end of the first connection pattern CNP1 may be electrically connected to a bridge pattern BRP through a corresponding second via hole VIH2 passing through the eighth insulating layer INS8. The bridge pattern BRP may be the bridge pattern BRP described with reference to FIG. 6. The bridge pattern BRP may be electrically connected to an anode electrode (refer to “AE” in FIG. 6) of the 11-th sub-pixel SPX11 through a third via hole (refer to “VIH3” in FIG. 6) passing through the ninth insulating layer INS9.

The sixth gate electrode may be one area of the second line WL2 overlapping the sixth active pattern ACT6.

The seventh transistor T7 may include a seventh active pattern ACT7 and a seventh gate electrode.

The seventh active pattern ACT7 may be one area of the first semiconductor pattern SCP1 overlapping the third line WL3. The first semiconductor pattern SCP1 may be formed of the first semiconductor layer. The seventh active pattern ACT7 may be a channel area of the seventh transistor T7.

One area of the first semiconductor pattern SCP1 connected to a first side (e.g., a lower side of the seventh active pattern ACT7 in a plan view) of the seventh active pattern ACT7 without overlapping the third line WL3 may be a first contact area. One area of the first semiconductor pattern SCP1 connected to a second side (e.g., an upper side of the seventh active pattern ACT7 in a plan view) of the seventh active pattern ACT7 without overlapping the third line WL3 may be a second contact area. The first contact area may be connected to the first side of the seventh active pattern ACT7, and may be connected to the first semiconductor pattern SCP1 of the sixth transistor T6. The second contact area may be connected to the second side of the seventh active pattern ACT7, and may be electrically connected to a first conductive pattern CP1.

The first conductive pattern CP1 may be formed of the fourth conductive layer CL4. The first conductive pattern CP1 may be electrically connected to the first semiconductor pattern SCP1 of the seventh transistor T7 through a corresponding first contactor CNT1 passing through the sixth insulating layer INS6, the fifth insulating layer INS5, the fourth insulating layer INS4, the third insulating layer INS3, and the second insulating layer INS2. Furthermore, the first conductive pattern CP1 may be electrically connected to the eighth line WL8 through a corresponding second contactor CNT2 passing through the sixth insulating layer INS6. In addition, the first conductive pattern CP1 may be electrically connected to a fourth connection pattern CNP4.

The fourth connection pattern CNP4 may be formed of the fifth conductive layer CL5. The fourth connection pattern CNP4 may be electrically connected to the first conductive pattern CP1 through a corresponding first via hole VIH1 passing through the seventh insulating layer INS7.

The seventh gate electrode may be one area of the third line WL3 overlapping the seventh active pattern ACT7.

The eighth transistor T8 may include an eighth active pattern ACT8 and an eighth gate electrode.

The eighth active pattern ACT8 may be one area of the first semiconductor pattern SCP1 overlapping the third line WL3. The first semiconductor pattern SCP1 may be formed of the first semiconductor layer. The eighth active pattern ACT8 may be a channel area of the eighth transistor T8.

One area of the first semiconductor pattern SCP1 connected to a first side (e.g., an upper side of the eighth active pattern ACT8 in a plan view) of the eighth active pattern ACT8 without overlapping the third line WL3 may be a first contact area. One area of the first semiconductor pattern SCP1 connected to a second side (e.g., a lower side of the eighth active pattern ACT8 in a plan view) of the eighth active pattern ACT8 without overlapping the third line WL3 may be a second contact area. The first contact area may be connected to the first side of the eighth active pattern ACT8, and may be electrically connected to the twelfth line WL12. The second contact area may be connected to the second side of the eighth active pattern ACT8, and may be electrically connected to the second conductive pattern CP2.

The twelfth line WL12 may be formed of the fourth conductive layer CL4, and may be electrically connected to the first contact area of the first semiconductor pattern SCP1 of the eighth transistor T8 through a first contactor CNT1 passing through the sixth insulating layer INS6, the fifth insulating layer INS5, the fourth insulating layer INS4, the third insulating layer INS3, and the second insulating layer INS2.

The second conductive pattern CP2 may be formed of the fourth conductive layer CL4, and may be electrically connected to the second contact area of the first semiconductor pattern SCP1 of the eighth transistor T8 through a first contactor CNT1 passing through the sixth insulating layer INS6, the fifth insulating layer INS5, the fourth insulating layer INS4, the third insulating layer INS3, and the second insulating layer INS2. Furthermore, the second conductive pattern CP2 may be electrically connected to the first semiconductor pattern SCP1 of the fifth transistor T5 through a first contactor CNT1 passing through the sixth insulating layer INS6, the fifth insulating layer INS5, the fourth insulating layer INS4, the third insulating layer INS3, and the second insulating layer INS2.

The eighth gate electrode may be one area of the third line WL3 overlapping the eighth active pattern ACT8.

The storage capacitor Cst may include a lower electrode LE and an upper electrode UE.

The lower electrode LE may be integrally formed with the first gate electrode GE1. The lower electrode LE may be formed of the first conductive layer CL1.

The upper electrode UE may overlap the lower electrode LE, and may be formed of the second conductive layer CL2. The upper electrode UE may include an opening OPN formed by removing a portion thereof. One area of the lower electrode LE overlapping the upper electrode UE may be exposed through the opening OPN. The upper electrode UE may be electrically connected to the third conductive pattern CP3.

According to the embodiment described above, the first sup-pixel unit SPU1 may include the 11-th sub-pixel SPX11 and the 12-th sub-pixel SPX12, and the second sub-pixel unit SPU2 may include the 13-th sub-pixel SPX13 and the 14-th sub-pixel SPX14. In each of the first and second sub-pixel units SPU1 and SPU2, each vertical bridge line may be positioned adjacent to an edge of the corresponding sub-pixel unit. For example, in the first sub-pixel unit SPU1, the first vertical bridge line BRL1_V may be positioned adjacent to a left edge of the first sub-pixel unit SPU1, and the second vertical bridge line BRL2_V may be positioned adjacent to a right edge of the first sub-pixel unit SPU1. In the second sub-pixel unit SPU2, the third vertical bridge line BRL3_V may be positioned adjacent to a left edge of the second sub-pixel unit SPU2, and the fourth vertical bridge line BRL4_V may be positioned adjacent to a right edge of the second sub-pixel unit SPU2.

According to the embodiment described above, the dummy electrode DME may be positioned on the boundary portion between the first sub-pixel unit SPU1 and the second sub-pixel unit SPU2 (or the boundary portion between the 12-th sub-pixel SPX12 and the 13-th sub-pixel SPX13). The dummy electrode DME may be positioned between the second vertical bridge line BRL2_V from among the vertical bridge lines disposed adjacent to the edges of the first sub-pixel unit SPU1 and the third vertical bridge line BRL3_V from among the vertical bridge lines disposed adjacent to the edges of the second sub-pixel unit SPU2.

The dummy electrode DME may be formed of the fifth conductive layer CL5, and may be integrally formed with the third connection pattern CNP3 (or a second auxiliary conductive pattern ACP2) of the 13-th sub-pixel SPX13 and thus electrically connected to the third vertical bridge line BRL3_V. The dummy electrode DME may be electrically connected to the first horizontal bridge line BRL1_H through a first via hole VIH1 in the boundary portion between the 12-th sub-pixel SPX12 and the 13-th sub-pixel SPX13. The first via hole VIH1 may correspond to the position of the dummy electrode DME. For example, in a plan view, the first via hole VIH1 may overlap the dummy electrode DME in the boundary portion between the 12-th sub-pixel SPX12 and the 13-th sub-pixel SPX13. Overlapping the dummy electrode DME, one first via hole VIH1 may be positioned in the boundary portion between the 12-th sub-pixel SPX12 and the 13-th sub-pixel SPX13 (or the boundary portion between the first sub-pixel unit SPU1 and the second sub-pixel unit SPU2).

According to the embodiment described above, in a plan view, the second vertical bridge line BRL2_V and the third vertical bridge line BRL3_V may be disposed to be spaced from each other with the dummy electrode DME provided therebetween. For example, in a plan view, the second vertical bridge line BRL2_V may be positioned on the left side of the dummy electrode DME, and the third bridge line BRL3_V may be positioned on the right side of the dummy electrode DME.

In a plan view, the second data line D2 and the third data line D3 may be disposed to be spaced from each other with the dummy electrode DME provided therebetween. In a plan view, the second data line D2 may be disposed on the left side of the dummy electrode DME, and may be positioned outside the second vertical bridge line BRL2_V based on the dummy electrode DME. In other words, in a plan view, the second vertical bridge line BRL2_V may be positioned closer to the dummy electrode DME than is the second data line D2. In a plan view, the third data line D3 may be disposed on the right side of the dummy electrode DME, and may be positioned outside the third vertical bridge line BRL3_V based on the dummy electrode DME. In other words, in a plan view, the third vertical bridge line BRL3_V may be positioned closer to the dummy electrode DME than is the third data line D3.

According to the embodiment described above, a distance d1 between the second vertical bridge line BRL2_V and the third vertical bridge line BRL3_V may be smaller (or narrower) than a distance d2 between the second data line D2 and the third data line D3.

In the embodiment described above, the dummy electrode DME has been described as being integrally formed with the third connection pattern CNP3 (or the second auxiliary conductive pattern ACP2) of the 13-th sub-pixel SPX13 and thus electrically connected to the third vertical bridge line BRL3_V, but is not limited thereto. In one or more embodiments, the dummy electrode DME may be integrally formed with the third connection pattern CNP3 (or a first auxiliary conductive pattern ACP1) of the 12-th sub-pixel SPX12 and thus electrically connected to the second vertical bridge line BRL2_V. In this case, the dummy electrode DME may electrically connect the first horizontal bridge line BRL1_H and the second vertical bridge line BRL2_V.

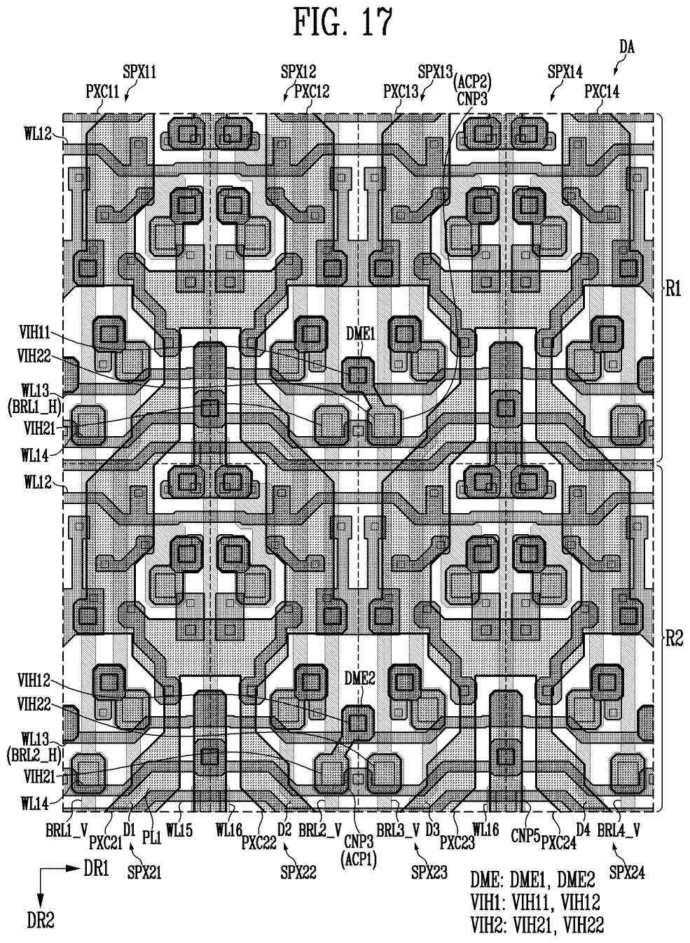

FIG. 17 is a schematic plan view illustrating sub-pixels arranged in the first and second pixel rows R1 and R2 positioned in one area of the display area DA of the display device in accordance with one or more embodiments.

For the sake of convenience in explanation, FIG. 17 illustrates only components included in the fourth conductive layer, the fifth conductive layer, and the sixth conductive layer in the sub-pixels arranged in the first and second pixel rows R1 and R2.

The following description with reference to FIG. 17 will be focused on differences from that of the foregoing embodiments to avoid redundant explanation.

Referring to FIG. 17, an 11-th sub-pixel SPX11 (or a first sub-pixel), a 12-th sub-pixel SPX12 (or a second sub-pixel), a 13-th sub-pixel SPX13 (or a third sub-pixel), and a 14-th sub-pixel SPX14 (or a fourth sub-pixel) may be arranged in the first pixel row R1 along the first direction DR1. A 21-th sub-pixel SPX21 (or a first sub-pixel), a 22-th sub-pixel SPX22 (or a second sub-pixel), a 23-th sub-pixel SPX23 (or a third sub-pixel), and a 24-th sub-pixel SPX24 (or a fourth sub-pixel) may be arranged in the second pixel row R2 along the first direction DR1.

The 11-th sub-pixel SPX11 may include an 11-th pixel circuit PXC11. The 12-th sub-pixel SPX12 may include a 12-th pixel circuit PXC12. The 13-th sub-pixel SPX13 may include a 13-th pixel circuit PXC13. The 14-th sub-pixel SPX14 may include a 14-th pixel circuit PXC14. The 21-th sub-pixel SPX21 may include a 21-th pixel circuit PXC21. The 22-th sub-pixel SPX22 may include a 22-th pixel circuit PXC22. The 23-th sub-pixel SPX23 may include a 23-th pixel circuit PXC23. The 24-th sub-pixel SPX24 may include a 24-th pixel circuit PXC24. A first vertical bridge line BRL1_V may be provided in common to the 11-th sub-pixel SPX11 and the 21-th sub-pixel SPX21 that are adjacent to each other in the second direction DR2. A second vertical bridge line BRL2_V may be provided in common to the 12-th sub-pixel SPX12 and the 22-th sub-pixel SPX22 that are adjacent to each other in the second direction DR2. A third vertical bridge line BRL3_V may be provided in common to the 13-th sub-pixel SPX13 and the 23-th sub-pixel SPX23 that are adjacent to each other in the second direction DR2. A fourth vertical bridge line BRL4_V may be provided in common to the 14-th sub-pixel SPX14 and the 24-th sub-pixel SPX24 that are adjacent to each other in the second direction DR2. In each of the first and second pixel rows R1 and R2, each of the first to fourth vertical bridge lines BRL1_V to BRL4_V may be electrically connected to the third connection pattern CNP3 through a corresponding second via hole VIH2.

In the first pixel row R1, the 11-th sub-pixel SPX11 and the 12-th sub-pixel SPX12 may form a first sub-pixel unit (refer to “SPU1” in FIG. 14). The 13-th sub-pixel SPX13 and the 14-th sub-pixel SPX14 may form a second sub-pixel unit (refer to “SPU2” in FIG. 14). In the second pixel row R2, the 21-th sub-pixel SPX21 and the 22-th sub-pixel SPX22 may form a first sub-pixel unit SPU1. The 23-th sub-pixel SPX23 and the 24-th sub-pixel SPX24 may form a second sub-pixel unit SPU2.

In each of the first and second pixel rows R1 and R2, the dummy electrode DME may be positioned in a boundary portion between the first sub-pixel unit SPU1 and the second sub-pixel unit SPU2 (or positioned between the first sub-pixel unit SPU1 and the second sub-pixel unit SPU2). For example, in the first pixel row R1, a first dummy electrode DME1 may be positioned on a boundary portion between the first sub-pixel unit SPU1 and the second sub-pixel unit SPU2 (or a boundary portion between the 12-th sub-pixel SPX12 and the 13-th sub-pixel SPX13). In the second pixel row R2, a second dummy electrode DME2 may be positioned on a boundary portion between the first sub-pixel unit SPU1 and the second sub-pixel unit SPU2 (or a boundary portion between the 22-th sub-pixel SPX22 and the 23-th sub-pixel SPX23).

The first dummy electrode DME1 and the second dummy electrode DEM2 may be formed of the fifth conductive layer (refer to “CL5” in FIG. 14). In one or more embodiments, each of the first and second dummy electrodes DME1 and DME2 may be electrically connected to a corresponding horizontal bridge line through one first via hole VIH1 in the boundary portion between the first sub-pixel unit SPU1 and the second sub-pixel unit SPU2. For example, the first dummy electrode DME1 may be electrically connected to a first horizontal bridge line BRL1_H (or a thirteenth line WL13) through one eleventh via hole VIH11 in the boundary portion between the first sub-pixel unit SPU1 and the second sub-pixel unit SPU2 of the first pixel row R1 (or in the boundary portion between the 12-th sub-pixel SPX12 and the 13-th sub-pixel SPX13). The second dummy electrode DME2 may be electrically connected to a second horizontal bridge line BRL2_H (or a thirteenth line WL13) through one 12-th via hole VIH12 in the boundary portion between the first sub-pixel unit SPU1 and the second sub-pixel unit SPU2 of the second pixel row R2 (or in the boundary portion between the 22-th sub-pixel SPX22 and the 23-th sub-pixel SPX23).

In one or more embodiments, the first dummy electrode DME1 may be integrally formed with the third connection pattern CNP3 (or the second auxiliary conductive pattern ACP2) of the 13-th sub-pixel SPX13. The third connection pattern CNP3 (or the second auxiliary conductive pattern ACP2) may be electrically connected to a third vertical bridge line BRL3_V through a 22-th via hole VIH22. Since the first dummy electrode DME1 is electrically connected to the first horizontal bridge line BRL1_H through the 11-th via hole VIH11, the first horizontal bridge line BRL1_H may be electrically connected to the third vertical bridge line BRL3_V.

In one or more embodiments, the second dummy electrode DME2 may be integrally formed with a third connection pattern CNP3 (or a first auxiliary conductive pattern ACP1) of the 22-th sub-pixel SPX22. The third connection pattern CNP3 (or the first auxiliary conductive pattern ACP1) may be electrically connected to the second vertical bridge line BRL2_V through a 21-th via hole VIH21. Because the second dummy electrode DME2 is electrically connected to the second horizontal bridge line BRL2_H through the 12-th via hole VIH12, the second horizontal bridge line BRL2_H may be electrically connected to the second vertical bridge line BRL2_V.

In the first pixel row R1, the first horizontal bridge line BRL1_H may be electrically connected to the first dummy electrode DME1 through the 11-th via hole VIH11, and may be electrically connected to the third vertical bridge line BRL3_V through the first dummy electrode DME1. In the second pixel row R2, the second horizontal bridge line BRL2_H may be electrically connected to the second dummy electrode DME2 through the 12-th via hole VIH12, and may be electrically connected to the second vertical bridge line BRL2_V through the second dummy electrode DME2.

In an odd-numbered pixel row (e.g., the first pixel row R1) of the display area DA, the dummy electrode DME (e.g., the first dummy electrode DME1) positioned in the boundary portion between the first sub-pixel unit SPU1 and the second sub-pixel unit SPU2 may be electrically connected to a vertical bridge line disposed adjacent to the dummy electrode DME from among the sub-pixels included in one of the first and second sub-pixel units SPU1 and SPU2. In an even-numbered pixel row of the display area DA, the dummy electrode DME (e.g., the second dummy electrode DME2) positioned in the boundary portion between the first sub-pixel unit SPU1 and the second sub-pixel unit SPU2 may be electrically connected to a vertical bridge line disposed adjacent to the dummy electrode DME from among the sub-pixels included in a remaining one of the first and second sub-pixel units SPU1 and SPU2. Hence, the dummy electrode DME (e.g., the first dummy electrode DME1) positioned in the odd-numbered pixel row and the dummy electrode DME (e.g., the second dummy electrode DME2) positioned in the even-numbered pixel row may be respectively electrically connected to different vertical bridge lines.

According to the embodiment described above, the first via holes VIH1 and the dummy electrodes DME electrically connecting the horizontal bridge lines and the vertical bridge lines in one area of the display area DA may be positioned in the same column (or the same line) in the second direction DR2 in a plan view. For example, the first dummy electrode DME1 positioned in the first pixel row R1 and the second dummy electrode DME2 positioned in the second pixel row R2 may be positioned in the same column (or the same line) in the second direction DR2. The 11-th via hole VIH11 positioned in the first pixel row R1 and the 12-th via hole VIH12 positioned in the second pixel row R2 may be positioned in the same column (or the same line). In this case, the first and second dummy electrodes DME1 and DME2 (or the dummy electrodes DME) and the 11-th and 12-th via holes VIH11 and VIH12 (or the first via holes VIH1) may be positioned in a specific area of the display area DA (e.g., the boundary portion between the first sub-pixel unit SPU1 and the second sub-pixel unit SPU2 in each pixel row). That is, in the display area DA, the dummy electrodes DME and the first via holes VIH1 may be intensively positioned in the specific area (e.g., the boundary portion between the first sub-pixel unit SPU1 and the second sub-pixel unit SPU2 in each pixel row). In this case, design constraints associated with positioning connection components (e.g., the dummy electrode DME and the first via hole VIH1) for electrically connecting the vertical bridge line and the horizontal bridge line for each pixel row in one area of the display area DA may be reduced. Accordingly, design optimization for the vertical bridge lines and the horizontal bridge lines in the display area becomes possible, thereby securing a valid space in each sub-pixel.

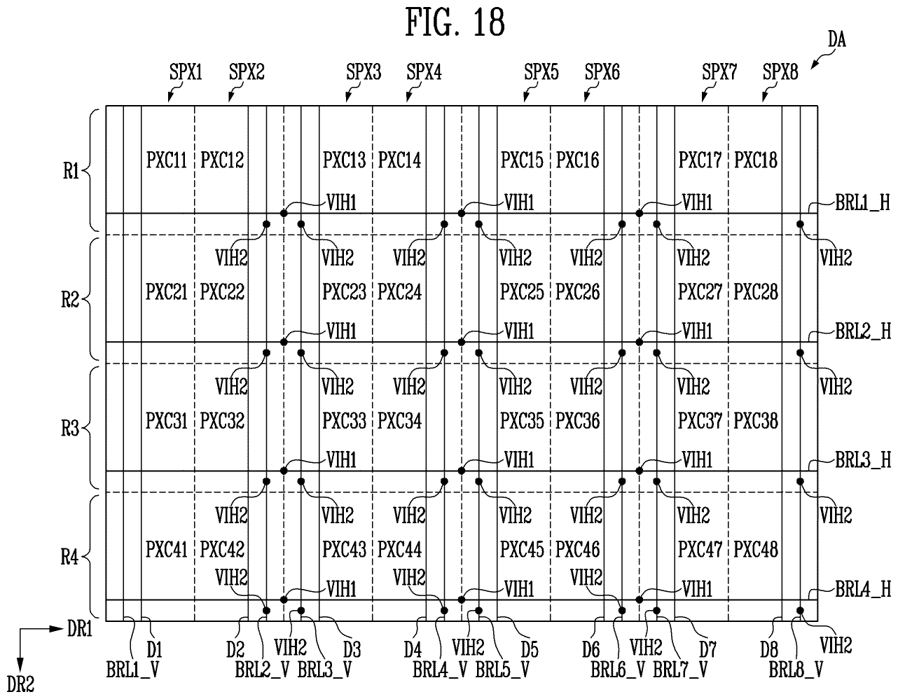

FIG. 18 is a schematic view illustrating positions of first via holes VIH1 and second via holes VIH2 in one area of the display area DA of the display device in accordance with one or more embodiments.

For the sake of convenient in explanation, FIG. 18 illustrates only some signal lines in sub-pixels arranged in each of the first to fourth pixel rows R1 to R4.

The following description with reference to FIG. 18 will be focused on differences from that of the foregoing embodiments to avoid redundant explanation.

Referring to FIG. 18, the display area DA may be divided into pixel rows R1 to R4. The pixel rows R1 to R4 may extend in the first direction DR1, and may be arranged along the second direction DR2. Each of the pixel rows R1 to R4 may include first to eighth sub-pixels SPX1 to SPX8. Each of the first to eighth sub-pixels SPX1 to SPX8 may include a pixel circuit.

In one or more embodiments, in each of the first to fourth pixel rows R1 to R4, the sub-pixels SPX1 to SPX8 may be arranged in the order of the first sub-pixel SPX1, the second sub-pixel SPX2, the third sub-pixel SPX3, the fourth sub-pixel SPX4, the fifth sub-pixel SPX5, the sixth sub-pixel SPX6, the seventh sub-pixel SPX7, and the eighth sub-pixel SPX8 in the first direction DR1. The first sub-pixel SPX1 and the second sub-pixel SPX2 may form a first sub-pixel unit (refer to “SPU1” in FIG. 4). The third sub-pixel SPX3 and the fourth sub-pixel SPX4 may form a second sub-pixel unit (refer to “SPU2” in FIG. 4). In one or more embodiments, the fifth sub-pixel SPX5 and the sixth sub-pixel SPX6 may form a first sub-pixel unit SPU1. The seventh sub-pixel SPX7 and the eighth sub-pixel SPX8 may form a second sub-pixel unit SPU2.

In the first pixel row R1, the pixel circuits PXC11 to PXC18 corresponding to the sub-pixels SPX1 to SPX8 of the first pixel row R1 may be arranged along the first direction DR1. In the second pixel row R2, the pixel circuits PXC21 to PXC28 corresponding to the sub-pixels SPX1 to SPX8 of the second pixel row R2 may be arranged along the first direction DR1. In the third pixel row R3, the pixel circuits PXC31 to PXC38 corresponding to the sub-pixels SPX1 to SPX8 of the third pixel row R3 may be arranged along the first direction DR1. In the fourth pixel row R4, the pixel circuits PXC41 to PXC48 corresponding to the sub-pixels SPX1 to SPX8 of the fourth pixel row R4 may be arranged along the first direction DR1.

A first horizontal bridge line BRL1_H may be disposed in the first pixel row R1. A second horizontal bridge line BRL2_H may be disposed in the second pixel row R2. A third horizontal bridge line BRL3_H may be disposed in the third pixel row R3. A fourth horizontal bridge line BRL4_H may be disposed in the fourth pixel row R4.

A first vertical bridge line BRL1_V and a first data line D1 may be disposed in the first sub-pixels SPX1 of the first to fourth pixel rows R1 to R4. A second vertical bridge line BRL2_V and a second data line D2 may be disposed in the second sub-pixels SPX2 of the first to fourth pixel rows R1 to R4. A third vertical bridge line BRL3_V and a third data line D3 may be disposed in the third sub-pixels SPX3 of the first to fourth pixel rows R1 to R4. A fourth vertical bridge line BRL4_V and a fourth data line D4 may be disposed in the fourth sub-pixels SPX4 of the first to fourth pixel rows R1 to R4. A fifth vertical bridge line BRL5_V and a fifth data line D5 may be disposed in the fifth sub-pixels SPX5 of the first to fourth pixel rows R1 to R4. A sixth vertical bridge line BRL6_V and a sixth data line D6 may be disposed in the sixth sub-pixels SPX6 of the first to fourth pixel rows R1 to R4. A seventh vertical bridge line BRL7_V and a seventh data line D7 may be disposed in the seventh sub-pixels SPX7 of the first to fourth pixel rows R1 to R4. An eighth vertical bridge line BRL8_V and an eighth data line D8 may be disposed in the eighth sub-pixels SPX8 of the first to fourth pixel rows R1 to R4.

In each of the first and second sub-pixel units SPU1 and SPU2, each vertical bridge line may be positioned adjacent to an edge of the corresponding sub-pixel unit. For example, in the first sub-pixel unit SPU1 of each of the first to fourth pixel rows R1 to R4, the first vertical bridge line BRL1_V (or the fifth vertical bridge line BRL5_V) and the second vertical bridge line BRL2_V (or the sixth vertical bridge line BRL6_V) may be positioned adjacent to edges of the first sub-pixel unit SPU1. Furthermore, in the second sub-pixel unit SPU2 of each of the first to fourth pixel rows R1 to R4, the third vertical bridge line BRL3_V (or the seventh vertical bridge line BRL7_V) and the fourth vertical bridge line BRL4_V (or the eighth vertical bridge line BRL8_V) may be positioned adjacent to edges of the second sub-pixel unit SPU2.

In one or more embodiments, in each of the first to fourth pixel rows R1 to R4, a first via hole VIH1 may be positioned in the boundary portion between the first sub-pixel unit SPU1 and the second sub-pixel unit SPU2. The first via hole VIH1 may be formed by removing a portion of an insulating layer, e.g., the seventh insulating layer (refer to “INS7” in FIG. 16), positioned between the horizontal bridge line and the dummy electrode disposed in each pixel row, and may be a connection point electrically connecting the horizontal bridge line and the dummy electrode.

In each of the first to fourth pixel rows R1 to R4, two second via holes VIH2 may be disposed in diagonal directions from the first via hole VIH1. The two second via holes VIH2 may be electrically connected to corresponding vertical bridge lines in the boundary portion between the first sub-pixel unit SPU1 and the second sub-pixel unit SPU2.

The first via holes VIH1 positioned in the first pixel row R1, the first via holes VIH1 positioned in the second pixel row R2, the first via holes VIH1 positioned in the third pixel row R3, and the first via holes VIH1 positioned in the fourth pixel row R4 may be disposed in the same columns (or the same lines) in the second direction DR2. Hence, in the display area DA, the first via holes VIH1 may be intensively positioned in only a specific area (e.g., the boundary portion between the first sub-pixel unit SPU1 and the second sub-pixel unit SPU2 in each of the first to fourth pixel rows R1 to R4). In this case, design constraints for electrical connection between the horizontal bridge lines and the vertical bridge lines in each pixel row may be reduced, and a valid space may be secured in some sub-pixels included in each pixel row.

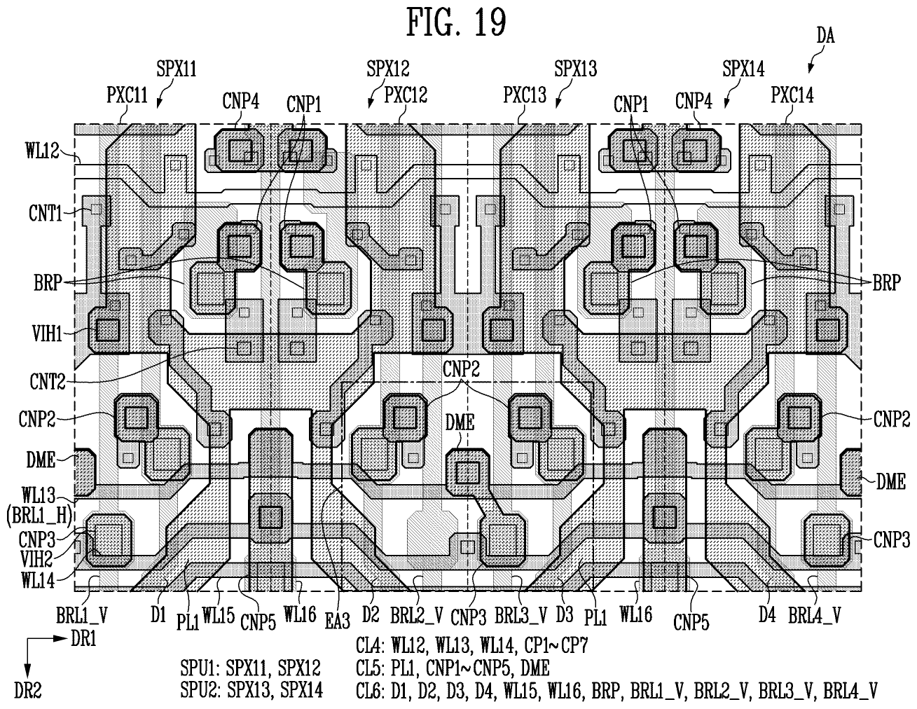

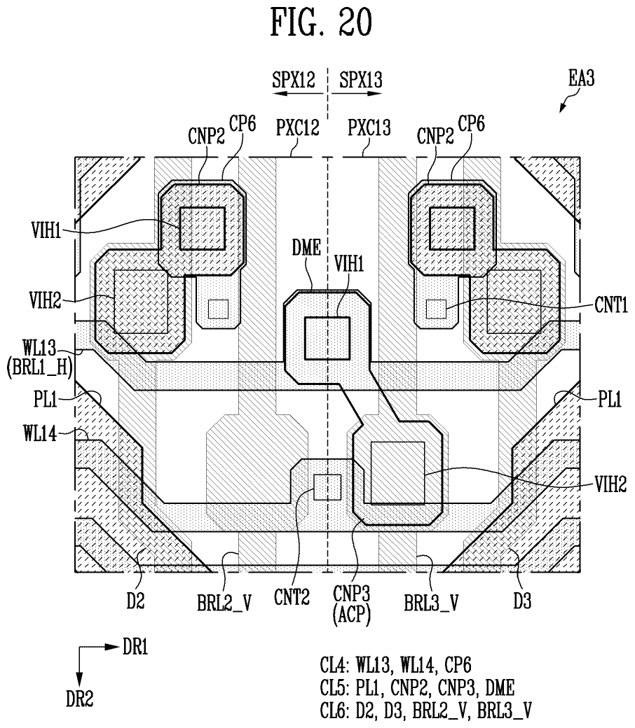

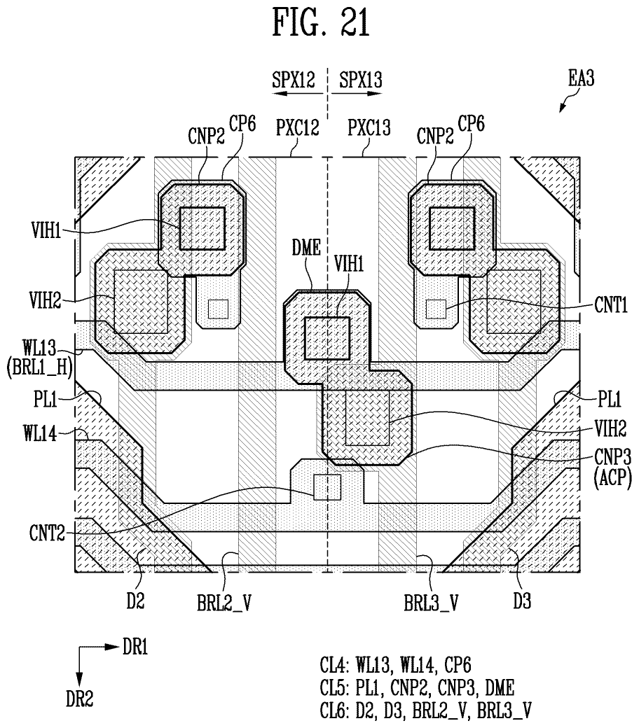

FIG. 19 is a schematic plan view illustrating sub-pixels positioned in one area of the display area DA of the display device in accordance with one or more embodiments. FIGS. 20 and 21 are enlarged schematic views illustrating portion EA3 of FIG. 19.

For the sake of convenience in explanation, FIGS. 19-21 illustrate only components included in the fourth conductive layer CL4, the fifth conductive layer CL5, and the sixth conductive layer CL6 in the sub-pixels arranged in the same pixel row (e.g., the first pixel row).

The description with reference to FIGS. 19-21 will be focused on differences from the above-mentioned embodiments so as to avoid redundant description.

1 Referring to FIGS. 19-21, an 11-th sub-pixel SPX11 (or a first sub-pixel), a 12-th sub-pixel SPX12 (or a second sub-pixel), a 13-th sub-pixel SPX13 (or a third sub-pixel), and a 14-th sub-pixel SPX14 (or a fourth sub-pixel) may be arranged along the first direction DR1 in the display area DA. The 11-th sub-pixel SPX11 and the 12-th sub-pixel SPX12 may form a first sub-pixel unit SPU1. The 13-th sub-pixel SPX13 and the 14-th sub-pixel SPX14 may form a second sub-pixel unit SPU2.

The dummy electrode DME may be positioned on a boundary portion between the first sub-pixel unit SPU1 and the second sub-pixel unit SPU2 (or a boundary portion between the 12-th sub-pixel SPX12 and the 13-th sub-pixel SPX13). The dummy electrode DME may be formed of the fifth conductive layer CL5, and may be electrically connected to the first horizontal bridge line BRL1_H (or the thirteenth line WL13) formed of the fourth conductive layer CL4 through a first via hole VIH1 passing through the seventh insulating layer (refer to “INS7” in FIG. 16). The dummy electrode DME may be integrally formed with the third connection pattern CNP3 (or the auxiliary conductive pattern ACP) of the 13-th sub-pixel SPX13 of the second sub-pixel unit SPU2. Hence, the dummy electrode DME may be electrically and physically connected to the third connection pattern CNP3. The dummy electrode DME and the auxiliary conductive pattern ACP (or the third connection pattern CNP3 of the 13-th sub-pixel SPX13) that are integrally formed may have one or more shapes, as shown in FIGS. 20 and 21, in the boundary portion between the first sub-pixel unit SPU1 and the second sub-pixel unit SPU2.

In a plan view, the second vertical bridge line BRL2_V disposed in the 12-th sub-pixel SPX12 and the third vertical bridge line BRL3_V disposed in the 13-th sub-pixel SPX13 may be disposed to be spaced from each other with the dummy electrode DME provided therebetween. In one or more embodiments, the second vertical bridge line BRL2_V disposed in the 12-th sub-pixel SPX12 may have a shape substantially identical or similar to that of the third vertical bridge line BRL3_V, as shown in FIG. 20, but is not limited thereto. In one or more embodiments, as illustrated in FIG. 21, the second vertical bridge line BRL2_V may have a shape different from that of the third vertical bridge line BRL3_V.

The second and third vertical bridge lines BRL2_V and BRL3_V may be formed of the sixth conductive layer CL6. The third vertical bridge line BRL3_V may be electrically connected to the third connection pattern CNP3 of the 13-th sub-pixel SPX13 through a second via hole VIH2 passing through the eighth insulating layer (refer to “INS8” in FIG. 16).

The first horizontal bridge line BRL1_H may be electrically connected to the third vertical bridge line BRL3_V through the dummy electrode DME (or the auxiliary conductive pattern ACP). The third vertical bridge line BRL3_V may be electrically connected to a corresponding fan-out line disposed in the fan-out area (refer to “FTA” in FIG. 2) so as to supply a certain signal transmitted from the fan-out line to the first horizontal bridge line BRL1_H. The first horizontal bridge line BRL1_H may be electrically connected to a corresponding data line positioned in the first area (refer to “DA1” in FIG. 2) of the display area DA so as to supply the certain signal (e.g., a data signal) to the data line.

In one or more embodiments, the 12-th sub-pixel SPX12 of the first sub-pixel unit SPU1 may not be provided with the third connection pattern CNP3 (or the auxiliary conductive pattern). In other words, the third connection pattern CNP3 may be omitted in the 12-th sub-pixel SPX12. In this case, the second via hole VIH2 formed to electrically connect the third connection pattern CNP3 to the second vertical bridge line BRL2_V disposed in the 12-th sub-pixel SPX12 may be omitted, thereby reducing design constraints associated with positioning the second via hole VIH2. Consequently, a valid space secured in the 12-th sub-pixel SPX12 may be increased.

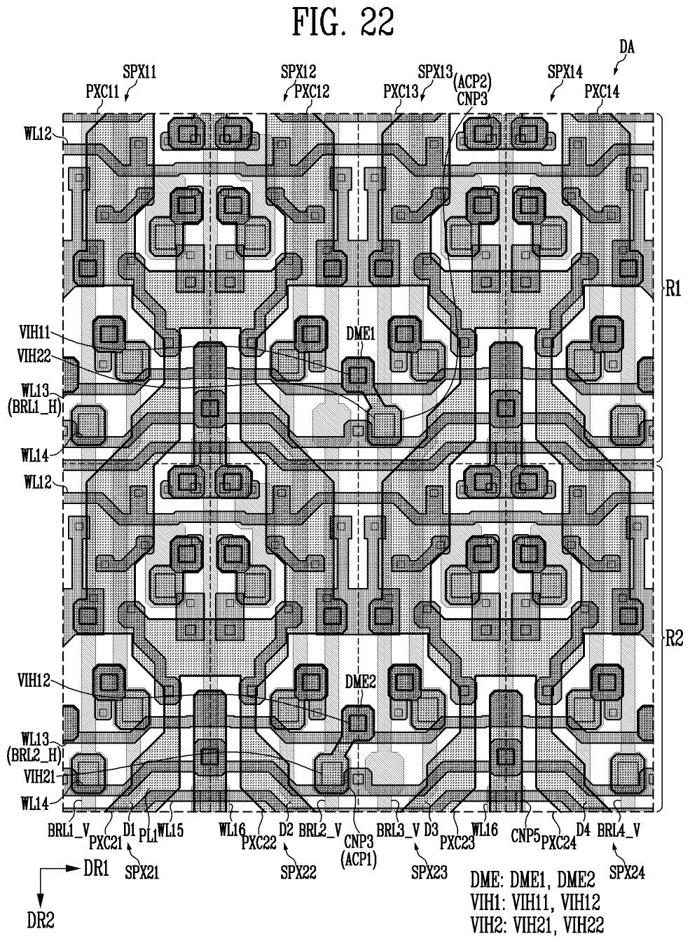

FIG. 22 is a schematic plan view illustrating sub-pixels arranged in the first and second pixel rows R1 and R2 positioned in one area of the display area DA of the display device in accordance with one or more embodiments.

The following description with reference to FIG. 22 will be focused on differences from that of the foregoing embodiments to avoid redundant explanation.

Referring to FIG. 22, in the first pixel row R1, the 11-th sub-pixel SPX11 and the 12-th sub-pixel SPX12 may form a first sub-pixel unit (refer to “SPU1” in FIG. 19). The 13-th sub-pixel SPX13 and the 14-th sub-pixel SPX14 may form a second sub-pixel unit (refer to “SPU2” in FIG. 19). In the second pixel row R2, the 21-th sub-pixel SPX21 and the 22-th sub-pixel SPX22 may form a first sub-pixel unit SPU1. The 23-th sub-pixel SPX23 and the 24-th sub-pixel SPX24 may form a second sub-pixel unit SPU2.

In each of the first to fourth pixel rows R1 to R2, the dummy electrode DME may be positioned in a boundary portion between the first sub-pixel unit SPU1 and the second sub-pixel unit SPU2. For example, the first dummy electrode DME1 may be positioned on the boundary portion between the first sub-pixel unit SPU1 and the second sub-pixel unit SPU2 (or the boundary portion between the 12-th sub-pixel SPX12 and the 13-th sub-pixel SPX13). In the second pixel row R2, the second dummy electrode DME2 may be positioned on a boundary portion between the first sub-pixel unit SPU1 and the second sub-pixel unit SPU2 (or a boundary portion between the 22-th sub-pixel SPX22 and the 23-th sub-pixel SPX23).

The first dummy electrode DME1 may be electrically connected to the first horizontal bridge line BRL1_H (or the thirteenth line WL13) through one 11-th via hole VIH11 in the boundary portion between the first sub-pixel unit SPU1 and the second sub-pixel unit SPU2 of the first pixel row R1 (or in the boundary portion between the 12-th sub-pixel SPX12 and the 13-th sub-pixel SPX13). The second dummy electrode DME2 may be electrically connected to the second horizontal bridge line BRL2_H (or the thirteenth line WL13) through one 12-th via hole VIH12 in the boundary portion between the first sub-pixel unit SPU1 and the second sub-pixel unit SPU2 of the second pixel row R2 (or in the boundary portion between the 22-th sub-pixel SPX22 and the 23-th sub-pixel SPX23).

The first dummy electrode DME1 may be integrally formed with the third connection pattern CNP3 (or the second auxiliary conductive pattern ACP2) of the 13-th sub-pixel SPX13. The third connection pattern CNP3 (or the second auxiliary conductive pattern ACP2) may be electrically connected to the third vertical bridge line BRL3_V through a 22-th via hole VIH22. Because the first dummy electrode DME1 is electrically connected to the first horizontal bridge line BRL1_H through the 11-th via hole VIH11, the first horizontal bridge line BRL1_H may be electrically connected to the third vertical bridge line BRL3_V.

The second dummy electrode DME2 may be integrally formed with the third connection pattern CNP3 (or the first auxiliary conductive pattern ACP1) of the 22-th sub-pixel SPX22. The third connection pattern CNP3 (or the first auxiliary conductive pattern ACP1) may be electrically connected to the second vertical bridge line BRL2_V through a 21-th via hole VIH21. Because the second dummy electrode DME2 is electrically connected to the second horizontal bridge line BRL2_H through the 12-th via hole VIH12, the second horizontal bridge line BRL2_H may be electrically connected to the second vertical bridge line BRL2_V.

In an odd-numbered pixel row (e.g., the first pixel row R1) in the display area DA, one of the two vertical bridge lines positioned in the boundary portion between the first sub-pixel unit SPU1 and the second sub-pixel unit SPU2, for example, the third vertical bridge line BRL3_V of the pair consisting of the second vertical bridge line BRL2_V and the third vertical bridge line BRL3_V, may be electrically connected to the first dummy electrode DME1 through the 22-th via hole VIH22 (or the corresponding second via hole VIH2). In an even-numbered pixel row (e.g., the second pixel row R2) in the display area DA, the second vertical bridge line BRL2_V of the pair consisting of the second vertical bridge line BRL2_V and the third vertical bridge line BRL3_V, positioned in the boundary portion between the first sub-pixel unit SPU1 and the second sub-pixel unit SPU2, may be electrically connected to the first dummy electrode DME1 through the 21-th via hole VIH21 (or the corresponding second via hole VIH2).

In one or more embodiments, a separate conductive pattern corresponding to the third connection pattern CNP3 (or the second auxiliary conductive pattern ACP2) of the 13-th sub-pixel SPX13 may not be disposed in the 12-th sub-pixel SPX12 disposed in the first pixel row R1. In this case, one second via hole for electrically connecting the second vertical bridge line BRL2_V and the conductive pattern may be omitted in the first pixel row R1. Consequently, design constraints associated with positioning the one second via hole may be reduced, thereby increasing the valid space in the 12-th sub-pixel SPX12.

In one or more embodiments, a separate conductive pattern corresponding to the third connection pattern CNP3 (or the first auxiliary conductive pattern ACP1) of the 22-th sub-pixel SPX22 may not be disposed in the 23-th sub-pixel SPX23 disposed in the second pixel row R2. In this case, one second via hole for electrically connecting the third vertical bridge line BRL3_V and the conductive pattern may be omitted in the second pixel row R2. Consequently, design constraints associated with positioning the one second via hole may be reduced, thereby increasing the valid space in the 23-th sub-pixel SPX23.

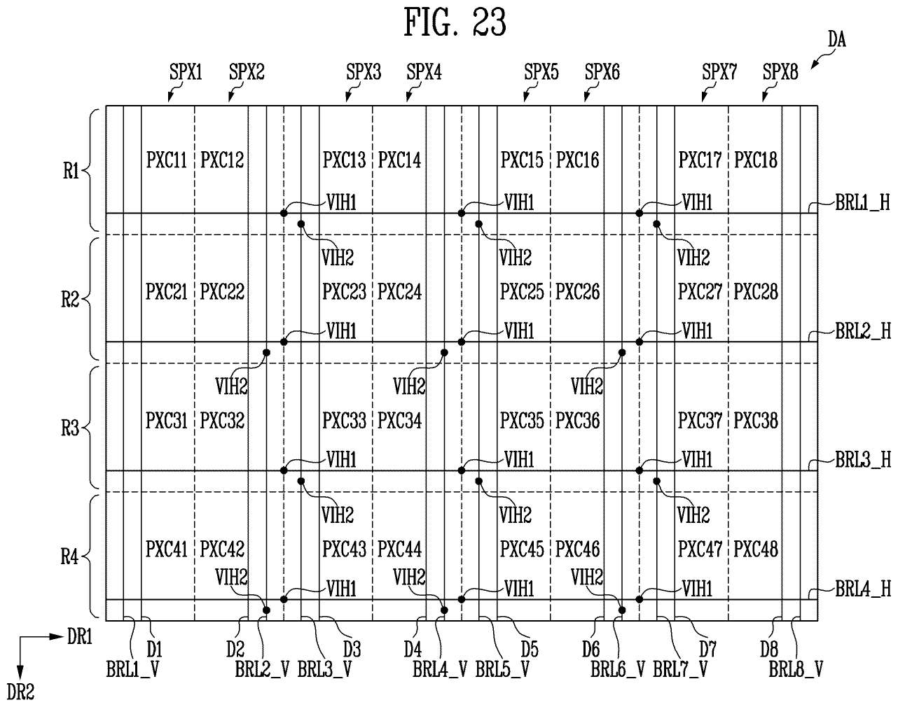

FIG. 23 is a schematic view illustrating positions of first via holes VIH1 and second via holes VIH2 in one area of the display area DA of the display device in accordance with one or more embodiments.

For the sake of convenient in explanation, FIG. 23 illustrates only some signal lines in sub-pixels arranged in each of the first to fourth pixel rows R1 to R4.

The following description with reference to FIG. 23 will be focused on differences from that of the foregoing embodiments to avoid redundant explanation.

Referring to FIG. 23, in each of the first to fourth pixel rows R1 to R4, a first via hole VIH1 may be positioned in the boundary portion between the first sub-pixel unit (refer to “SPU1” in FIG. 19) and the second sub-pixel unit (refer to “SPU2” in FIG. 19). The first via hole VIH1 may be formed by removing a portion of an insulating layer, e.g., the seventh insulating layer (refer to “INS7” in FIG. 16), positioned between the horizontal bridge line and the dummy electrode disposed in each pixel row, and may be a connection point electrically connecting the horizontal bridge line and the dummy electrode.

In each of the first to fourth pixel rows R1 to R4, one second via hole VIH2 may be disposed in a diagonal direction from the first via hole VIH1. For example, in an odd-numbered pixel row (e.g., each of the first and third pixel rows R1 and R3), one second via hole VIH2 may be disposed in a right diagonal direction from the first via hole VIH1. Furthermore, in an even-numbered pixel row (e.g., each of the second and fourth pixel rows R2 and R4), one second via hole VIH2 may be disposed in a left diagonal direction from the first via hole VIH1. Therefore, the second via hole VIH2 positioned in the odd-numbered pixel row and the second via hole VIH2 positioned in the even-numbered pixel row may be positioned in different columns rather than being positioned in the same column (or the same line). Furthermore, the second via holes VIH2 of the first and third pixel rows R1 and R3 that are odd-numbered pixel rows may be positioned in the same column (or the same line). The second via holes VIH2 of the second and fourth pixel rows R2 and R4 that are even-numbered pixel rows may be positioned in the same column (or the same line).

The first via holes VIH1 positioned in the first pixel row R1, the first via holes VIH1 positioned in the second pixel row R2, the first via holes VIH1 positioned in the third pixel row R3, and the first via holes VIH1 positioned in the fourth pixel row R4 may be disposed in the same columns (or the same lines) in the second direction DR2. Hence, in the display area DA, the first via holes VIH1 may be intensively positioned in only a specific area (e.g., the boundary portion between the first sub-pixel unit SPU1 and the second sub-pixel unit SPU2 in each of the first to fourth pixel rows R1 to R4). In this case, design restrictions for electrical connection between the horizontal bridge lines and the vertical bridge lines in each pixel row may be reduced, and a valid space may be secured in some sub-pixels included in each pixel row.

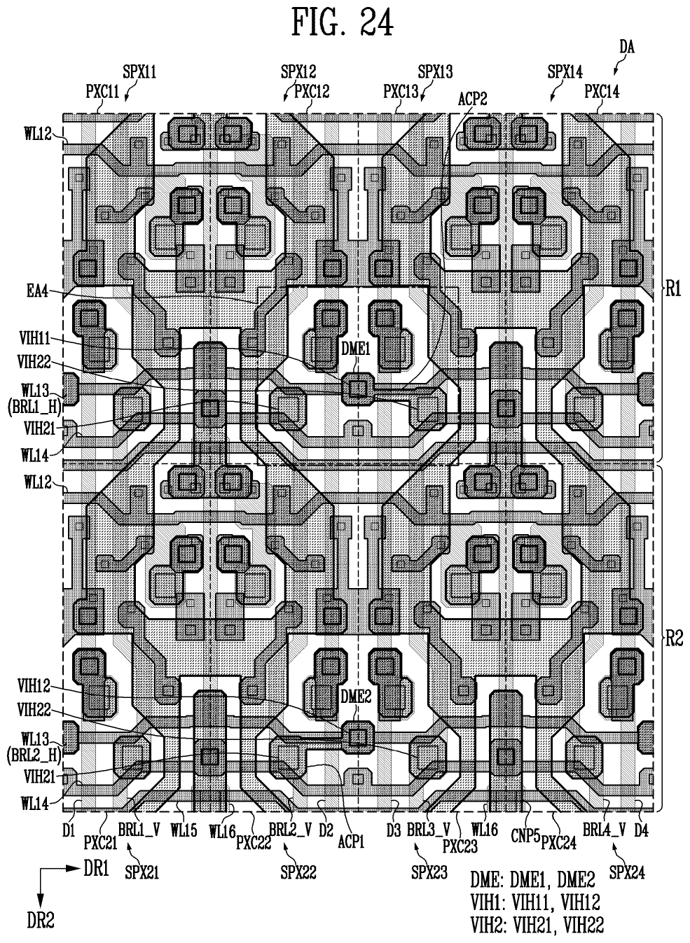

In the embodiments described above, the vertical bridge lines have been described as being disposed adjacent to edges of the corresponding sub-pixel unit, but are not limited thereto. In one or more embodiments, data lines may be disposed adjacent to the edges of the corresponding sub-pixel unit. The foregoing structure will be described below with reference to FIGS. 24-26.

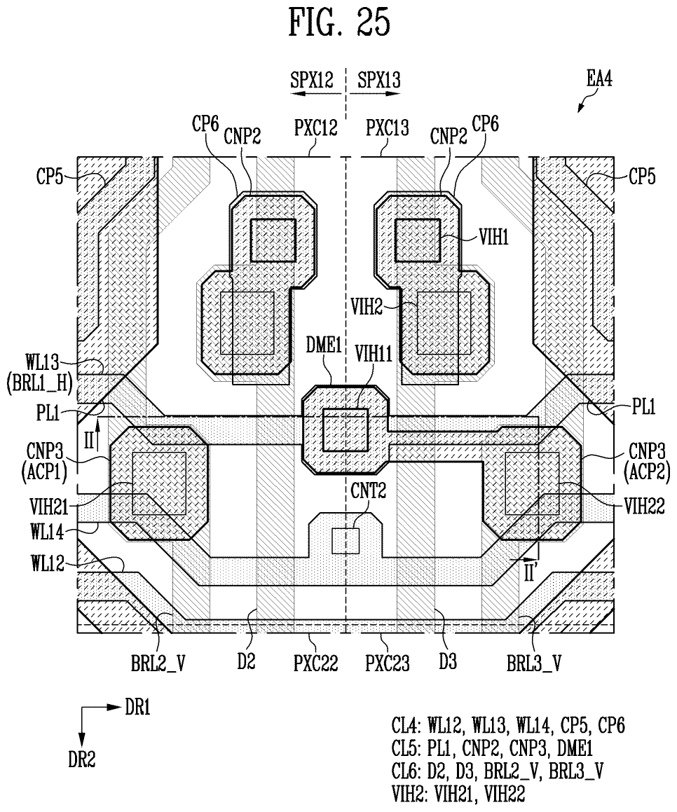

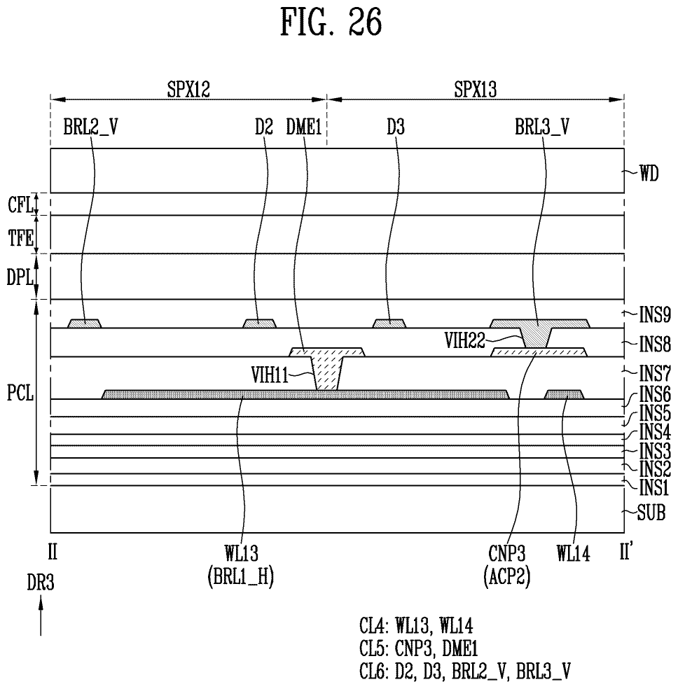

FIG. 24 is a schematic plan view illustrating sub-pixels arranged in the first and second pixel rows R1 and R2 positioned in one area of the display area DA of the display device in accordance with one or more embodiments. FIG. 25 is an enlarged schematic view showing a portion EA4 of FIG. 24. FIG. 26 is a schematic sectional view taken along the line II-II′ of FIG. 25.

For the sake of convenience in explanation, FIGS. 24-26 illustrate only components included in the fourth conductive layer CL4, the fifth conductive layer CL5, and the sixth conductive layer CL6 in the sub-pixels arranged in the same pixel row (e.g., the first pixel row).

The description with reference to FIGS. 24-26 will be focused on differences from the above-mentioned embodiments so as to avoid redundant description.

Referring to FIGS. 24-26, in the first pixel row R1, the 11-th sub-pixel SPX11 and the 12-th sub-pixel SPX12 may form a first sub-pixel unit (refer to “SPU1” in FIG. 19). The 13-th sub-pixel SPX13 and the 14-th sub-pixel SPX14 may form a second sub-pixel unit (refer to “SPU2” in FIG. 19). In the second pixel row R2, the 21-th sub-pixel SPX21 and the 22-th sub-pixel SPX22 may form a first sub-pixel unit SPU1. The 23-th sub-pixel SPX23 and the 24-th sub-pixel SPX24 may form a second sub-pixel unit SPU2.

In each of the first to fourth pixels of the pixel rows R1 and R2, the dummy electrode DME may be positioned in a boundary portion between the first sub-pixel unit SPU1 and the second sub-pixel unit SPU2. For example, the first dummy electrode DME1 may be positioned on the boundary portion between the first sub-pixel unit SPU1 and the second sub-pixel unit SPU2 (or the boundary portion between the 12-th sub-pixel SPX12 and the 13-th sub-pixel SPX13). In the second pixel row R2, the second dummy electrode DME2 may be positioned on a boundary portion between the first sub-pixel unit SPU1 and the second sub-pixel unit SPU2 (or a boundary portion between the 22-th sub-pixel SPX22 and the 23-th sub-pixel SPX23).

The first dummy electrode DME1 and the second dummy electrode DEM2 may be formed of the fifth conductive layer CL5. The first dummy electrode DME1 may be electrically connected to the first horizontal bridge line BRL1_H (or the thirteenth line WL13) through one 11-th via hole VIH11 in the boundary portion between the first sub-pixel unit SPU1 and the second sub-pixel unit SPU2 of the first pixel row R1 (or in the boundary portion between the 12-th sub-pixel SPX12 and the 13-th sub-pixel SPX13). The second dummy electrode DME2 may be electrically connected to the second horizontal bridge line BRL2_H (or the thirteenth line WL13) through one 12-th via hole VIH12 in the boundary portion between the first sub-pixel unit SPU1 and the second sub-pixel unit SPU2 of the second pixel row R2 (or in the boundary portion between the 22-th sub-pixel SPX22 and the 23-th sub-pixel SPX23).

In each of the first and second sub-pixel units SPU1 and SPU2, each data line may be positioned adjacent to an edge of the corresponding sub-pixel unit. For example, in the first sub-pixel unit SPU1 of each of the first and second pixel rows R1 and R2, the first data line D1 may be positioned adjacent to a left edge of the first sub-pixel unit SPU1. The second data line D2 in the first sub-pixel unit SPU1 may be positioned adjacent to a right edge of the first sub-pixel unit SPU1. In the second sub-pixel unit SPU2 of each of the first and second pixel rows R1 and R2, the third data line D3 may be positioned adjacent to a left edge of the second sub-pixel unit SPU2. The fourth data line D4 in the second sub-pixel unit SPU2 may be positioned adjacent to a right edge of the second sub-pixel unit SPU2.

In one or more embodiments, in each of the first and second sub-pixel units SPU1 and SPU2, each vertical bridge line may be positioned farther from the edge of the corresponding sub-pixel unit than is the corresponding data line. For example, the first vertical bridge line BRL1_V may be positioned farther from the corresponding edge of the first sub-pixel unit SPU1 than is the first data line D1. The second vertical bridge line BRL2_V may be positioned farther from the corresponding edge of the first sub-pixel unit SPU1 than is the second data line D2. The third vertical bridge line BRL3_V may be positioned farther from the corresponding edge of the second sub-pixel unit SPU2 than is the third data line D3. The fourth vertical bridge line BRL4_V may be positioned farther from the corresponding edge of the second sub-pixel unit SPU2 than is the fourth data line D4. In other words, the first vertical bridge line BRL1_V may be positioned more inward in the first sub-pixel unit SPU1 than is the first data line D1. The second vertical bridge line BRL2_V may be positioned more inward in the first sub-pixel unit SPU1 than is the second data line D2. The third vertical bridge line BRL3_V may be positioned more inward in the second sub-pixel unit SPU2 than is the third data line D3. The fourth vertical bridge line BRL4_V may be positioned more inward in the second sub-pixel unit SPU2 than is the fourth data line D4.

In one or more embodiments, in a plan view, the second data line D2 and the third data line D3 may be disposed to be spaced from each other with the dummy electrode DME provided therebetween.

In a plan view, the second data line D2 may be positioned on a left side of each of the first and second dummy electrodes DME1 and DME2, and may be positioned inside the second vertical bridge line BRL2_V based on the first and second dummy electrodes DME1 and DME2. In other words, in a plan view, the second data line D2 may be positioned closer to each of the first and second dummy electrodes DME1 and DME2 than is the second vertical bridge line BRL2_V.

In a plan view, the third data line D3 may be positioned on a right side of each of the first and second dummy electrodes DME1 and DME2, and may be positioned inside the third vertical bridge line BRL3_V based on the first and second dummy electrodes DME1 and DME2. In other words, in a plan view, the third data line D3 may be positioned closer to each of the first and second dummy electrodes DME1 and DME2 than is the third vertical bridge line BRL3_V.

A distance between the second data line D2 and the third data line D3 may be less than a distance between the second vertical bridge line BRL2_V and the third vertical bridge line BRL3_V.

In one or more embodiments, the first dummy electrode DME1 may be integrally formed with the second auxiliary conductive pattern ACP2 disposed in the 13-th sub-pixel SPX13. The second auxiliary conductive pattern ACP2 may be electrically connected to the third vertical bridge line BRL3_V through a 22-th via hole VIH22. Because the first dummy electrode DME1 is electrically connected to the first horizontal bridge line BRL1_H through the 11-th via hole VIH11, the first horizontal bridge line BRL1_H may be electrically connected to the third vertical bridge line BRL3_V.

In one or more embodiments, the second dummy electrode DME2 may be integrally formed with the first auxiliary conductive pattern ACP1 disposed in the 22-th sub-pixel SPX22. The first auxiliary conductive pattern ACP1 may be electrically connected to the second vertical bridge line BRL2_V through a 21-th via hole VIH21. Because the second dummy electrode DME2 is electrically connected to the second horizontal bridge line BRL2_H through the 12-th via hole VIH12, the second horizontal bridge line BRL2_H may be electrically connected to the second vertical bridge line BRL2_V.

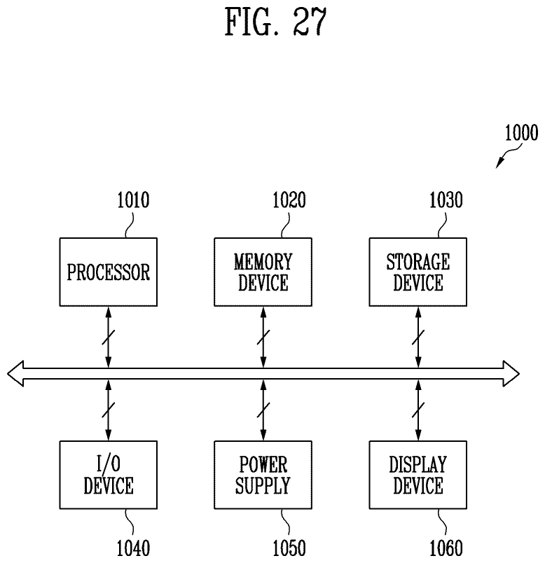

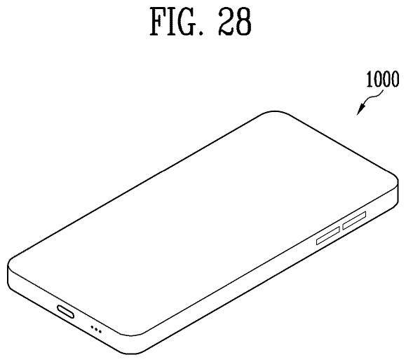

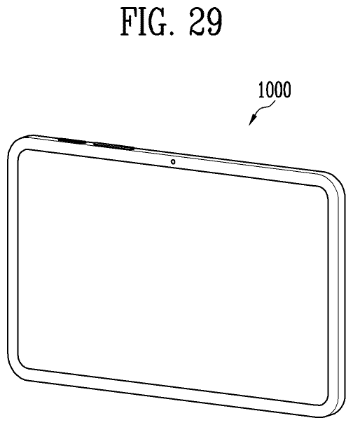

FIG. 27 is a schematic block diagram illustrating an electronic device in accordance with an embodiment. FIG. 28 is a schematic diagram illustrating an example where the electronic device of FIG. 27 is implemented as a smartphone. FIG. 29 is a schematic diagram illustrating an example where the electronic device of FIG. 27 is implemented as a tablet computer.

Referring to FIGS. 27 to 29, the electronic device 1000 may include a processor 1010, a memory device 1020, a storage device 1030, an input/output (I/O) device 1040, a power supply 1050, and a display device 1060. The display device 1060 may be the display device DD of FIGS. 1 and 2. The electronic device 1000 may further include various ports for communication with a video card, a sound card, a memory card, a USB device, or other systems. In an embodiment, as illustrated in FIG. 28, the electronic device 1000 may be implemented as a smartphone. In an embodiment, as illustrated in FIG. 29, the electronic device 1000 may be implemented as a tablet computer. However, the aforementioned examples are illustrative, and the electronic device 1000 is not necessarily limited to the aforementioned examples. For example, the electronic device 1000 may be implemented as a cellular phone, a video phone, a smartpad, a smartwatch, a navigation device for vehicles, a computer monitor, a laptop computer, a head-mounted display device, or the like.

The processor 1010 may perform specific calculations or tasks. In an embodiment, the processor 1010 may be a micro processor, a central processing unit, an application processor, or the like. The processor 1010 may be connected to other components through an address bus, a control bus, a data bus, and the like. In an embodiment, the processor 1010 may be connected to an expansion bus such as a peripheral component interconnect (PCI) bus.

The memory device 1020 may store data needed to perform the operation of the electronic device 1000. For example, the memory device 1020 may include non-volatile memory devices such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, and a ferroelectric random access memory (FRAM) device, and/or volatile memory devices such as a dynamic random access memory (DRAM) device, a static random access memory (SRAM) device, a mobile DRAM device, and so on.

The storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be included in the I/O device 1040.

The power supply 1050 may supply power needed to perform the operation of the electronic device 1000. For example, the power supply 1050 may be a power management integrated circuit (PMIC).

The display device 1060 may display an image corresponding to visual information of the electronic device 1000. Here, the display device 1060 may be an organic light emitting diode (OLED) display device or a quantum dot light emitting display device, but is not necessarily limited thereto. The display device 1060 may be connected to other components through the buses or other communication links.

In accordance with one or more embodiments of the present disclosure, in one area of a display area, an electrode pattern (or a dummy electrode) electrically connected to a horizontal bridge line through a first via hole may be disposed in a boundary portion between a first sub-pixel unit and a second sub-pixel unit arranged in each pixel row.

In accordance with one or more embodiments of the present disclosure, in each pixel row, the electrode pattern (or the first via hole) may be disposed in the boundary portion between the first sub-pixel unit and the second sub-pixel unit. Consequently, the electrode pattern (or the first via hole) may be intensively positioned in a specific area of the display area. Accordingly, design constraints due to positioning the electrode pattern (or the first via hole) in each pixel row of the display area may be reduced, thereby making it possible to optimize the design of the horizontal bridge line and the vertical bridge line in the display area. As a result, a valid space in each sub-pixel may be increased.

The effects, aspects, and features of the present disclosure are not limited by the foregoing, and other various effects, aspects, and features are anticipated herein.

While various embodiments have been described above, those skilled in the art will appreciate that various modifications, additions and substitutions are possible, without departing from the spirit and scope of the present disclosure.

Therefore, the embodiments disclosed in this specification are only for illustrative purposes rather than limiting the technical spirit of the present disclosure. The scope of the present disclosure may be defined by the accompanying claims and their equivalents.

What is claimed is:

1. A display device, comprising:
a first sub-pixel and a second sub-pixel arranged along a first direction, and forming a first sub-pixel unit;
a third sub-pixel and a fourth sub-pixel arranged along the first direction, and forming a second sub-pixel unit adjacent to the first sub-pixel unit;
a pixel circuit in each of the first to the fourth sub-pixels;
a vertical bridge line extending in a second direction, and located in each of the first and the second sub-pixel units;
a data line extending in the second direction, and spaced from the vertical bridge line;
a horizontal bridge line extending in the first direction; and
a dummy electrode in a boundary portion between the first sub-pixel unit and the second sub-pixel unit, and electrically connected to the horizontal bridge line,
wherein the dummy electrode is electrically connected to at least one of the first and the second sub-pixel units.

2. The display device according to claim 1, wherein, in a plan view, the vertical bridge line is located closer to an edge of each of the first and the second sub-pixel units than the data line is.

3. The display device according to claim 2,
wherein the vertical bridge line comprises a first vertical bridge line, a second vertical bridge line, a third vertical bridge line, and a fourth vertical bridge line arranged along the first direction,
wherein the first vertical bridge line overlaps the pixel circuit of the first sub-pixel,
wherein the second vertical bridge line overlaps the pixel circuit of the second sub-pixel,
wherein the third vertical bridge line overlaps the pixel circuit of the third sub-pixel,
wherein the fourth vertical bridge line overlaps the pixel circuit of the fourth sub-pixel, and
wherein, in a plan view, the dummy electrode is between the second vertical bridge line and the third vertical bridge line.

4. The display device according to claim 3,
wherein the data line comprises a first data line spaced from the first vertical bridge line, a second data line spaced from the second vertical bridge line, a third data line spaced from the third vertical bridge line, and a fourth data line spaced from the fourth vertical bridge line, and
wherein, in a plan view, the second vertical bridge line is located closer to the dummy electrode than the second data line is, and the third vertical bridge line is closer to the dummy electrode than the third data line is.

5. The display device according to claim 4, further comprising:
a first via layer on the horizontal bridge line, and including a first via hole exposing one area of the horizontal bridge line; and
a second via layer on the dummy electrode, and including a second via hole exposing one area of the dummy electrode,
wherein the first to the fourth vertical bridge lines are on the second via layer, and the dummy electrode is between the first via layer and the second via layer, and
wherein the dummy electrode is electrically connected to the horizontal bridge line through the first via hole.

6. The display device according to claim 5,
wherein a first end of the dummy electrode is electrically connected to the horizontal bridge line through the first via hole, and
wherein a second end of the dummy electrode is electrically connected to at least one of the second vertical bridge line and the third vertical bridge line through the second via hole.

7. The display device according to claim 6, further comprising:
a first auxiliary conductive pattern under the second vertical bridge line between the first via layer and the second via layer of the second sub-pixel, and electrically connected to the second vertical bridge line; and
a second auxiliary conductive pattern under the third vertical bridge line between the first via layer and the second via layer of the third sub-pixel, and electrically connected to the third vertical bridge line,
wherein the first and the second auxiliary conductive patterns are in a same layer as the dummy electrode, and
wherein the dummy electrode is integrally formed with at least one of the first or the second auxiliary conductive patterns.

8. The display device according to claim 6, further comprising an auxiliary conductive pattern under at least one of the second and the third vertical bridge lines between the first via layer and the second via layer,
wherein the auxiliary conductive pattern is in a same layer as the dummy electrode, and is integrally formed with the dummy electrode.

9. The display device according to claim 1, wherein, in a plan view, the data line is closer to an edge of each of the first and the second sub-pixel units than the vertical bridge line is.

10. A display device, comprising:
a substrate having a display area including a first area and a second area, and a non-display area around at least one side of the display area;
a first sub-pixel and a second sub-pixel arranged along a first direction in each of first and second pixel rows of the substrate, and forming a first sub-pixel unit;
a third sub-pixel and a fourth sub-pixel arranged along the first direction in each of the first and second pixel rows of the substrate, and forming a second sub-pixel unit adjacent to the first sub-pixel unit;
a pixel circuit in each of the first to the fourth sub-pixels;
a vertical bridge line extending in a second direction, and in each of the first and the second sub-pixel units;
a data line extending in the second direction, and spaced from the vertical bridge line;
a first horizontal bridge line extending in the first pixel row in the first direction;
a second horizontal bridge line extending in the second pixel row in the first direction;
a first dummy electrode in the first pixel row in a boundary portion between the first sub-pixel unit and the second sub-pixel unit, and electrically connected to the first horizontal bridge line; and
a second dummy electrode in the second pixel row in the boundary portion between the first sub-pixel unit and the second sub-pixel unit, and electrically connected to the second horizontal bridge line,
wherein, in a plan view, the first dummy electrode and the second dummy electrode are in a same column.

11. The display device according to claim 10, wherein, in a plan view, the vertical bridge line is closer to an edge of each of the first and the second sub-pixel units than the data line is.

12. The display device according to claim 11,
wherein the vertical bridge line comprises a first vertical bridge line, a second vertical bridge line, a third vertical bridge line, and a fourth vertical bridge line arranged along the first direction in each of the first and the second pixel rows,
wherein the first vertical bridge line overlaps the pixel circuit of the first sub-pixel,
wherein the second vertical bridge line overlaps the pixel circuit of the second sub-pixel,
wherein the third vertical bridge line overlaps the pixel circuit of the third sub-pixel,
wherein the fourth vertical bridge line overlaps the pixel circuit of the fourth sub-pixel, and
wherein, in a plan view, each of the first and the second dummy electrodes is between the second vertical bridge line and the third vertical bridge line.

13. The display device according to claim 12,
wherein the data line comprises a first data line spaced from the first vertical bridge line, a second data line spaced from the second vertical bridge line, a third data line spaced from the third vertical bridge line, and a fourth data line spaced from the fourth vertical bridge line, and
wherein, in a plan view, the second vertical bridge line is closer to the first and the second dummy electrodes than the second data line is, and the third vertical bridge line is closer to the first and the second dummy electrodes than the third data line is.

14. The display device according to claim 12,
wherein the first dummy electrode is electrically connected to at least one of the second or the third vertical bridge lines, and
wherein the second dummy electrode is electrically connected to a remaining one of the second and the third vertical bridge lines.

15. The display device according to claim 14, further comprising:
a first auxiliary conductive pattern overlapping one area of the second vertical bridge line in the second sub-pixel of each of the first and the second pixel rows; and
a second auxiliary conductive pattern overlapping one area of the third vertical bridge line in the third sub-pixel of each of the first and the second pixel rows,
wherein the first and the second auxiliary conductive patterns are in a same layer as the first and the second dummy electrodes,
wherein the first dummy electrode is integrally formed with the second auxiliary conductive pattern, and
wherein the second dummy electrode is integrally formed with the first auxiliary conductive pattern.

16. The display device according to claim 15, further comprising:
a first via layer on the first and the second horizontal bridge lines, and including an 11-th via hole exposing one area of the first horizontal bridge line, and a 12-th via hole exposing one area of the second horizontal bridge line; and
a second via layer on the first and the second auxiliary conductive patterns, and including a 21-th via hole exposing one area of the first auxiliary conductive pattern, and a 22-th via hole exposing one area of the second auxiliary conductive pattern,
wherein the first to the fourth vertical bridge lines are on the second via layer, and
wherein the first and the second dummy electrodes and the first and the second auxiliary conductive patterns are between the first via layer and the second via layer.

17. The display device according to claim 16,
wherein the first dummy electrode is electrically connected to the first horizontal bridge line through the 11-th via hole, and the second auxiliary conductive pattern integrally formed with the first dummy electrode is electrically connected to the third vertical bridge line through the 22-th via hole,
wherein the second dummy electrode is electrically connected to the second horizontal bridge line through the 12-th via hole, and the first auxiliary conductive pattern integrally formed with the second dummy electrode is electrically connected to the second vertical bridge line through the 21-th via hole, wherein the 11-th via hole and the 12-th via hole are in the boundary portion between the first sub-pixel unit and the second sub-pixel unit, and
wherein the 11-th via hole and the 12-th via hole are in a same column, in a plan view.

18. The display device according to claim 14, further comprising:
a second auxiliary conductive pattern under the third vertical bridge line in the first pixel row, and overlapping one area of the third vertical bridge line; and
a first auxiliary conductive pattern under the second vertical bridge line in the second pixel row, and overlapping one area of the second vertical bridge line,
wherein the first dummy electrode is integrally formed with the second auxiliary conductive pattern, and
wherein the second dummy electrode is integrally formed with the first auxiliary conductive pattern.

19. The display device according to claim 10, wherein, in a plan view, the data line is closer to an edge of each of the first and the second sub-pixel units than is the vertical bridge line.

20. An electronic device, comprising:
a processor configured to provide input image data to a display device; and
the display device configured to display an image based on the input image data,
wherein the display device comprises:
a first sub-pixel and a second sub-pixel arranged along a first direction, and forming a first sub-pixel unit;
a third sub-pixel and a fourth sub-pixel arranged along the first direction, and forming a second sub-pixel unit adjacent to the first sub-pixel unit;
a pixel circuit in each of the first to the fourth sub-pixels;
a vertical bridge line extending in a second direction, and located in each of the first and the second sub-pixel units;
a data line extending in the second direction, and spaced from the vertical bridge line;
a horizontal bridge line extending in the first direction; and
a dummy electrode in a boundary portion between the first sub-pixel unit and the second sub-pixel unit, and electrically connected to the horizontal bridge line,
wherein the dummy electrode is electrically connected to at least one of the first and the second sub-pixel units.
